(19) United States
(12) Patent Application Publication
(10) Pub. No.: US 2026/0090469 A1
(43) Pub. Date: Mar. 26, 2026

(54) MICROELECTRONIC ASSEMBLIES WITH TAGS DISINTEGRATED FROM CACHE MEMORY

(71) Applicant: Intel Corporation, Santa Clara, CA (US)

(72) Inventors: Abhishek A. Sharma, Portland, OR (US); Wilfred Gomes, Portland, OR (US)

(73) Assignee: Intel Corporation, Santa Clara, CA (US)

(21) Appl. No.: 18/897,246

(22) Filed: Sep. 26, 2024

(51) Int. Cl. H01L 25/065; H10B 10/00; H10B 12/00; H10B 80/00

(52) U.S. Cl. CPC H10W 90/00; H10B 10/125; H10B 12/36; H10B 80/00; H10W 90/722

(57) ABSTRACT

Disclosed herein are microelectronic assemblies with tags disintegrated from cache memory, as well as related structures and techniques. In one aspect, a microelectronic assembly includes first and second dies stacked above one another in a stack of dies, where the first die includes cache memory with an array of memory cells and the second die includes tags for determining whether a requested piece of data is available in the cache memory. Cache memory may be implemented using DRAM cells to enable lower cost, higher memory cell density, and better power efficiency, while tags may be implemented using SRAM cells to realize higher speed and lower latency of memory operations.

### BACKGROUND

Cache memory is a small, high-speed memory located close to a central processing unit (CPU) that stores frequently accessed or recently used data from the main memory (e.g., from random-access memory (RAM)). The primary function of cache memory is to speed up data access for the CPU by providing faster access to this data compared to accessing it directly from the slower main memory.

Typically, cache memory is built using faster memory technologies such as Static Random-access Memory (SRAM), allowing it to respond to CPU requests much quicker than the main memory, which is typically built using Dynamic Random-access Memory (DRAM). The primary advantage of using DRAM for main memory instead of SRAM is related to cost and density, which makes DRAM more suitable for large-capacity main memory in most computing devices.

Cache memory uses tags to help manage the fast access to frequently used data by linking it to specific memory addresses. In the context of cache memory, a tag is a component of the cache directory used to identify which block of data in the cache corresponds to a specific address in the main memory. Tags play a crucial role in determining whether a requested piece of data is available in the cache (a cache hit) or needs to be fetched from the main memory (a cache miss).

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIGS. 1A-1D are schematic illustrations of stacks of dies in a microelectronic assembly, where tags are disintegrated from cache memory, according to some embodiments.

FIG. 2 is a side, cross-sectional view of one example of the microelectronic assembly of any of FIGS. 1A-1D with direct bonding interconnects (DBIs) between adjacent dies of a stack of dies, according to some embodiments.

FIG. 3 is a side, cross-sectional exploded view of a portion of the microelectronic assembly of FIG. 2, according to some embodiments.

FIG. 4 is a side, cross-sectional view of another example of the microelectronic assembly of any of FIGS. 1A-1D with solder-based die-to-die interconnects (DTDs) between adjacent dies of a stack of dies, according to some embodiments.

FIG. 5 is a cross-sectional side view of a gate-channel arrangement that may be included in transistors of tags and cache memory of microelectronic assemblies with tags disintegrated from cache memory, according to some embodiments.

FIGS. 6-10 are cross-sectional side views of example single-gate transistors that may be used in tags and cache memory of microelectronic assemblies with tags disintegrated from cache memory, according to some embodiments.

FIGS. 11-13 are cross-sectional side views of example double-gate transistors that may be used in tags and cache memory of microelectronic assemblies with tags disintegrated from cache memory, according to some embodiments.

FIGS. 14A and 14B are perspective and cross-sectional side views, respectively, of an example tri-gate transistor that may be used in tags and cache memory of microelectronic assemblies with tags disintegrated from cache memory, according to some embodiments.

FIGS. 15A and 15B are perspective and cross-sectional side views, respectively, of an example all-around transistor that may be used in tags and cache memory of microelectronic assemblies with tags disintegrated from cache memory, according to some embodiments.

FIG. 16 is an electric circuit diagram of an example 6-transistor (6T) SRAM cell, according to some embodiments.

FIG. 17 is an electric circuit diagram of an example DRAM cell, according to some embodiments.

FIG. 18 is an electric circuit diagram of an example SRAM tag, according to some embodiments.

FIG. 19 is a top view of a wafer and dies that may be included in a microelectronic component in accordance with any of the embodiments disclosed herein.

FIG. 20 is a side, cross-sectional view of an integrated circuit (IC) device that may be included in a microelectronic component in accordance with any of the embodiments disclosed herein.

FIG. 21 is a side, cross-sectional view of an IC device assembly that may include a microelectronic assembly in accordance with any of the embodiments disclosed herein.

FIG. 22 is a block diagram of an example electrical device that may include a microelectronic assembly in accordance with any of the embodiments disclosed herein.

### DETAILED DESCRIPTION

The systems, methods and devices of this disclosure each have several innovative aspects, no single one of which is solely responsible for all of the desirable attributes disclosed herein. Details of one or more implementations of the subject matter described in this specification are set forth in the description below and the accompanying drawings.

For purposes of illustrating microelectronic assemblies with tags disintegrated from cache memory, proposed herein, it might be useful to first understand phenomena that may come into play in some microelectronic assemblies where cache memory may be used. The following foundational information may be viewed as a basis from which the present disclosure may be properly explained. Such information is offered for purposes of explanation only and, accordingly, should not be construed in any way to limit the broad scope of the present disclosure and its potential applications.

As described above, cache memory is typically constructed using SRAM cells, while main memory utilizes DRAM cells, as this approach balances the strengths and weaknesses of each type of memory for their respective applications. SRAM has several significant advantages over DRAM, making SRAM more suitable for specific high-performance applications such as cache memory. For example, SRAM is much faster than DRAM. Since SRAM does not need to be refreshed like DRAM, it provides near-instantaneous data access. This faster access speed is crucial in applications like CPU caches (e.g., L1, L2, and L3 cache memory), where quick access to data is necessary to prevent the CPU from being bottlenecked by slower memory operations. SRAM does not require periodic refreshing to retain data, unlike DRAM, which needs constant refresh cycles to prevent data loss due to charge leakage in its capacitors. This makes SRAM more reliable for applications where consistent, high-speed access to data is needed without delays caused by refresh cycles. Because SRAM cells hold their data as long as power is supplied, there is no need for complex circuitry to refresh memory contents, unlike DRAM, which requires refresh controllers to manage the periodic refresh cycles. This makes SRAM easier to integrate into systems where memory control complexity needs to be minimized. SRAM has lower latency compared to DRAM, meaning it takes less time to access data. The latency in DRAM comes from the refresh operations and the need to read and pre-charge the memory before each access. SRAM's ability to provide instantaneous data access makes it ideal for real-time applications, such as processor caches, where minimizing delays is critical for performance. SRAM's speed and reliability make it a better choice for high-performance systems like cache memory, graphics memory, and embedded systems. These systems often prioritize performance and reliability over memory capacity, which aligns with SRAM's strengths.

Despite the notable advantages on some aspects, SRAM also has disadvantages over DRAM, particularly in terms of cost, capacity, and power efficiency. For example, SRAM cells are more expensive to manufacture compared to DRAM cells due to complex architecture of SRAM cells, which requires six transistors per memory cell, whereas DRAM only needs one transistor and one or more capacitors per cell. SRAM has lower memory density, meaning it stores less data per unit area compared to DRAM. This is again due to the fact that an SRAM cell requires more space (because of its 6-transistor design) than a DRAM cell. As a result, SRAM dies are larger and cannot offer the same large memory capacities that DRAM dies can, making DRAM more suitable for applications like main memory (e.g., system RAM) where high capacity is needed. SRAM consumes more power when storing large amounts of data because its transistors need continuous power to maintain their state. Even though it doesn't require refreshing like DRAM, the static power consumption can be higher, especially in large arrays. DRAM, while needing to be refreshed periodically, can be more power-efficient in high-density memory applications where maintaining the state is less costly than powering multiple transistors in SRAM. Due to these disadvantages, SRAM is primarily used in smaller, high-speed memory caches, while DRAM is used for larger main memory in computers and other devices.

In conventional implementations, tags are integrated within memory arrays of cache memory (i.e., tags are provided on the same die with the cache memory). To ease integration of tags on the same die with the memory cells of cache memory, both tags and cache memory are typically implemented using the same type of memory technology because implementing different memory technologies (e.g., SRAM and DRAM) on a single die is complicated and costly. Thus, since cache memory is typically built using SRAM cells, tags integrated on the same tie with cache memory are also built using SRAM cells.

Embodiments of the present disclosure are based on recognition that traditional methods of implementing cache memory with SRAM cells and integrating tags on the same die as SRAM cells may face substantial challenges as memory sizes are scaled to increasingly higher densities. To address these challenges, microelectronic assemblies with tags disintegrated from cache memory, as well as related structures and techniques, are disclosed. In one aspect, a microelectronic assembly includes first and second dies stacked above one another in a stack of dies, where the first die includes cache memory with an array of memory cells and the second die includes tags for determining whether a requested piece of data is available in the cache memory. In some embodiments, all of the tags for determining whether a requested piece of data is available in the cache memory may be included in the second die and no such tags may be present in the first die. Implementing tags for cache memory on a separate die from the cache memory itself not only leaves more space for the memory cells of the cache memory, thus advantageously increasing it's density, but also allows implementing cache memory and tags using different types of memory cells. For example, cache memory may be implemented using DRAM cells to enable lower cost, higher memory cell density (i.e., higher capacity), and better power efficiency, while tags may be implemented using SRAM cells to realize higher speed and lower latency of memory operations. Including the die with cache memory and the die with tags associated with the cache memory in a single stack of dies further allows maximizing speed and minimizing latency because signals between the die with cache memory and the die with tags don't have to travel through a microelectronic component such as an interposer, a package substrate, or a circuit board. Instead, the die with cache memory and the die with tags associated with the cache memory may be coupled to one another using DBIs or solder-based DTD interconnects (possibly with a compute die in between), which may lead to higher speed and lower latency of communications.

In the following detailed description, reference is made to the accompanying drawings that form a part hereof wherein like numerals designate like parts throughout, and in which is shown, by way of illustration, embodiments that may be practiced. It is to be understood that other embodiments may be utilized, and structural or logical changes may be made, without departing from the scope of the present disclosure. Therefore, the following detailed description is not to be taken in a limiting sense.

Any of the features discussed with reference to any of accompanying drawings herein may be combined with any other features to form a microelectronic assembly 100 with tags disintegrated from cache memory, as appropriate. A number of elements of the drawings are shared with others of the drawings; for ease of discussion, a description of these elements is not repeated, and these elements may take the form of any of the embodiments disclosed herein. Also for convenience, the phrase “dies 102” may be used to refer to the collection of dies 102-1, 102-2, and so on, the phrase “DB region 130” may be used to refer to the collection of DB regions 130-1, 130-2, and so on, etc. To not clutter the drawings, if multiple instances of certain elements are illustrated, only some of the elements may be labeled with a reference sign. The drawings are not necessarily to scale. Although many of the drawings illustrate rectilinear structures with flat walls and right-angle corners, this is simply for ease of illustration and may not reflect real-life process limitations which may cause various features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of with tags disintegrated from cache memory as described herein.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used to describe a range of dimensions, the phrase “between X and Y” represents a range that includes X and Y. When used to describe a location of an element, the phrase “between X and Y” represents a region that is spatially between element X and element Y. The terms “substantially,” “close,” “approximately,” “near,” and “about,” generally refer to being within +/−20%, e.g., within +/−5% or within +/−2%, of a target value based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−20%, e.g., within +/−5% or within +/−2%, of a target value based on the context of a particular value as described herein or as known in the art.

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. As used herein, the terms “package” and “IC package” are synonymous, as are the terms “die” and “IC die.” Furthermore, the terms “chip,” “chiplet,” “die,” and “IC die” may be used interchangeably herein.

Although certain elements may be referred to in the singular herein, such elements may include multiple sub-elements. For example, “a dielectric material” may include one or more dielectric materials. The terms “oxide,” “carbide,” “nitride,” etc. refer to compounds containing, respectively, oxygen, carbon, nitrogen, etc. The term “high-k dielectric” refers to a material having a higher dielectric constant than silicon oxide, while the term “low-k dielectric” refers to a material having a lower dielectric constant than silicon oxide. The term “insulating” and variations thereof (e.g., “insulative” or “insulator”) means “electrically insulating,” the term “conducting” and variations thereof (e.g., “conductive” or “conductor”) means “electrically conducting,” unless otherwise specified. With reference to optical signals and/or devices, components and elements that operate on or using optical signals, the term “conducting” can also mean “optically conducting.” The term “insulating material” refers to solid materials (and/or liquid materials that solidify after processing as described herein) that are substantially electrically nonconducting. They may include, as examples and not as limitations, organic polymers and plastics, and inorganic materials such as ionic crystals, porcelain, glass, silicon and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components. The term “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket, or portion of a conductive line or via).

The term “connected” may be used to describe a direct electrical connection between the things that are connected (e.g., with the things being in electrically conductive conduct and/or in physical contact, e.g., in direct contact or directly electrical connected), without any intermediary devices, while the term “coupled” may be used to describe either a direct electrical or magnetic connection between the things that are connected, or an indirect connection through one or more passive or active intermediary devices. Describing A and B are being “in contact” includes A and B being in direct physical contact, possibly with an interface that may form when A and B are brough into direct physical contact with one another.

The term “package substrate” may be used to describe any substrate material that facilitates the packaging together of any collection of semiconductor dies and/or other electrical components such as passive electrical components. As used herein, a package substrate may be formed of any material including, but not limited to, insulating materials such as resin impregnated glass fibers (e.g., printed circuit board (PCB) or Printed Wiring Boards (PWB)), glass, ceramic, silicon, silicon carbide, etc. In addition, as used herein, a package substrate may refer to a substrate that includes buildup layers (e.g., Ajinomoto Buildup Film (ABF) layers). In some embodiments, a package substrate may be a PCB or a multilayer package substrate that includes a core including glass, e.g., a core including a glass layer, where the glass layer may be bulk glass or a solid volume of glass, as opposed to, e.g., glass fiber reinforced polymers (i.e., in some embodiments, the glass layer does not include any glass fiber reinforced polymers).

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides (e.g., structures that guide and confine light waves), including optical fiber, optical splitters, optical combiners, optical couplers, and optical vias.

The term “metallization stack” may be used to refer to a stack of one or more interconnects for providing connectivity to different circuit components of an IC die/chip and/or a package substrate. The term “conductive trace” may be used to describe an electrically conductive element isolated by an insulating material. Within IC dies, such insulating material comprises interlayer low-k dielectric that is provided within the IC die. Within package substrates, and PCBs such insulating material may comprise organic materials such as ABF, polyimides, or epoxy resin. Such conductive lines are typically arranged in several levels, or several layers, of metallization stacks. The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

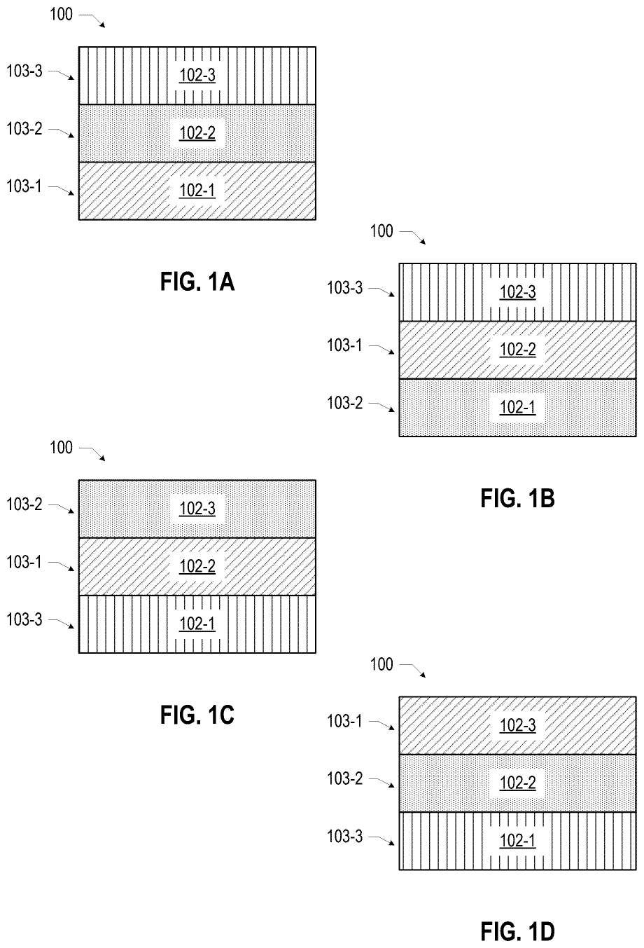

FIGS. 1A-1D are schematic illustrations of stacks of dies 102 in a microelectronic assembly 100, where tags are disintegrated from cache memory, according to some embodiments. Each of FIGS. 1A-1D illustrates a stack in which multiple dies 102 having different functionality are included. In particular, each of FIGS. 1A-1D illustrates a stack with three dies, individually labeled as a die 102-1, a die 102-2, and a die 102-3, where the die 102-2 is between the die 102-1 and the die 102-3 in the vertical stack of dies 102, although in other embodiments such stacks may include additional dies. In some embodiments, individual ones of the microelectronic assemblies 100 disclosed herein may serve as a system-in-package (SiP) in which multiple dies 102 having different functionality are included. In such embodiments, the microelectronic assembly 100 may be referred to as an SiP.

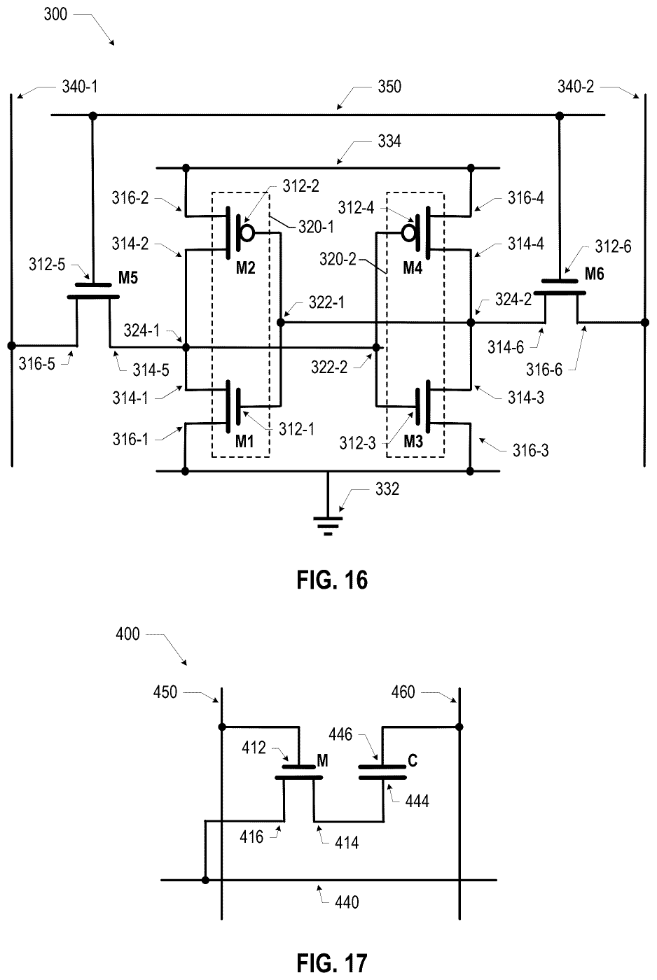

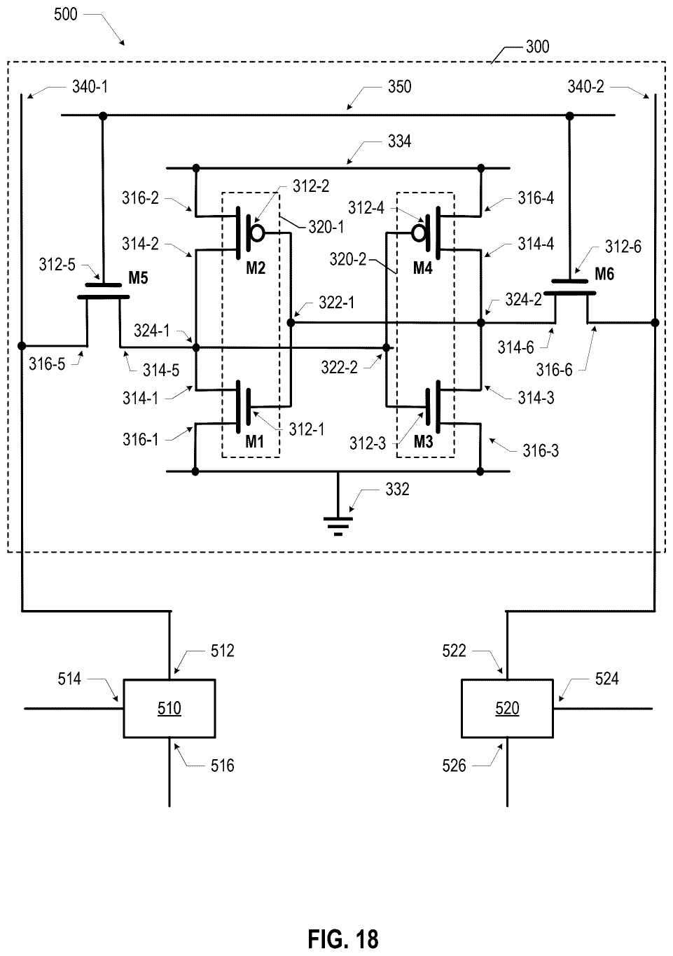

Different ones of the dies 102 of the microelectronic assembly 100 may differ in their functionality (i.e., different dies 102 may implement circuits with different functionality). One of the dies 102 may be a die on which cache memory is implemented (such a die referred to herein as a cache memory die 103-3). The cache memory of the cache memory die 103-3 may include a plurality of memory cells according to any suitable memory technology, e.g., a plurality of SRAM cells (e.g., a plurality of SRAM cells 300 as shown in FIG. 16), a plurality of DRAM cells (e.g., a plurality of DRAM cells 400 as shown in FIG. 17), or memory cells of any other technology. Another one of the of the dies 102 may be a die on which tags associated with the cache memory die are implemented (such a die referred to herein as a tags die 103-1). The tags of the tags die 103-1 may include a plurality of tags according to any suitable memory technology, e.g., a plurality of SRAM tags (e.g., a plurality of SRAM tags 500 as shown in FIG. 18). The third one of the dies 102 of the microelectronic assembly 100 may be a die on which logic circuitry (e.g., compute logic) for controlling operation of the tags of the tag die 103-1 and/or for controlling operation of the memory cells of the cache memory die 103-3 is implemented (such a die referred to herein as a compute die 103-2). Such logic circuitry may include a plurality of logic transistors, e.g., a plurality of complementary metal-oxide-semiconductor (CMOS) transistors and may be configured to, e.g., initiate that tags of the tags die 103-1 are to be used to determine whether a requested piece of data is available in the cache memory of the cache memory die 103-3. In some embodiments, the logic circuitry of the compute die 103-2 may be configured to fetch the requested piece of data from the cache memory die 103-3 once the tags of the tags die 103-1 output the result that the requested piece of data is available in the cache memory. In other embodiments, the tags of the tags die 103-1 may be configured to fetch the requested piece of data from the cache memory die 103-3 and provide it to the logic circuitry of the compute die once the tags output the result that the requested piece of data is available in the cache memory.

FIG. 1A illustrates an embodiment where the compute die 103-2 is between the tags die 103-1 at the bottom and the cache memory die 103-3 at the top (i.e., the die 102-1 is the tags die 103-1, the die 102-2 is the compute die 103-2, and the die 102-3 is the cache memory die 103-3). As shown in FIG. 1A, in such an embodiment, the top side of the tags die 103-1 may be communicatively and electrically connected with the bottom side of the compute die 103-2 (e.g., using DBIs or solder-based DTD interconnects), while the bottom side of the cache memory die 103-3 may be communicatively and electrically connected with the top side of the compute die 103-2 (e.g., also using DBIs or solder-based DTD interconnects).

FIG. 1B illustrates an embodiment where the tags die 103-1 is between the compute die 103-2 at the bottom and the cache memory die 103-3 at the top (i.e., the die 102-1 is the compute die 103-2, the die 102-2 is the tags die 103-1, and the die 102-3 is the cache memory die 103-3). As shown in FIG. 1B, in such an embodiment, the top side of the compute die 103-2 may be communicatively and electrically connected with a bottom side of the tags die 103-1 (e.g., using DBIs or solder-based DTD interconnects), while the bottom side of the cache memory die 103-3 may be communicatively and electrically connected with a top side of the tags die 103-1 (e.g., also using DBIs or solder-based DTD interconnects). Thus, the microelectronic assembly 100 of FIG. 1B is substantially the same as the microelectronic assembly 100 of FIG. 1A, but with the tags die 103-1 and the compute die 103-2 being swapped.

FIG. 1C illustrates an embodiment where the tags die 103-1 is between the cache memory die 103-3 at the bottom and the cache compute die 103-2 at the top (i.e., the die 102-1 is the cache memory die 103-3, the die 102-2 is the tags die 103-1, and the die 102-3 is the compute die 103-2). As shown in FIG. 1C, in such an embodiment, the top side of the cache memory die 103-3 may be communicatively and electrically connected with a bottom side of the tags die 103-1 (e.g., using DBIs or solder-based DTD interconnects), while the bottom side of the compute die 103-2 may be communicatively and electrically connected with a top side of the tags die 103-1 (e.g., also using DBIs or solder-based DTD interconnects). Thus, the microelectronic assembly 100 of FIG. 1C is substantially the same as the microelectronic assembly 100 of FIG. 1B, but with the cache memory die 103-3 and the compute die 103-2 being swapped.

FIG. 1D illustrates an embodiment where the compute die 103-2 is between the memory die 103-3 at the bottom and the cache tags die 103-1 at the top (i.e., the die 102-1 is the cache memory die 103-3, the die 102-2 is the compute die 103-2, and the die 102-3 is the tags die 103-1). As shown in FIG. 1D, in such an embodiment, the top side of the cache memory die 103-3 may be communicatively and electrically connected with a bottom side of the compute die 103-2 (e.g., using DBIs or solder-based DTD interconnects), while the bottom side of the tags die 103-1 may be communicatively and electrically connected with a top side of the compute die 103-2 (e.g., also using DBIs or solder-based DTD interconnects). Thus, the microelectronic assembly 100 of FIG. 1D is substantially the same as the microelectronic assembly 100 of FIG. 1A, but with the cache memory die 103-3 and the tags die 103-1 being swapped, or the microelectronic assembly 100 of FIG. 1D is substantially the same as the microelectronic assembly 100 of FIG. 1C, but with the compute die 103-2 and the tags die 103-1 being swapped.

FIGS. 1A-1D use different patterns to illustrate the tags die 103-1, the compute die 103-2, and the cache memory die 103-3. As shown in various embodiments of these drawings, it may be particularly advantageous (e.g., in terms of reduced latency) if the tags die 103-1 is adjacent to the compute die 103-2. As used herein, two dies of a stack of dies are described to as “adjacent” if they are connected to one another by solder-based DTD interconnects such as DBIs or solder-based DTD interconnects. The cache memory die 103-3 may be in any position with respect to the tags die 103-1 or the compute die 103-2, as long as it is in the same stack as the tags die 103-1 and the compute die 103-2.

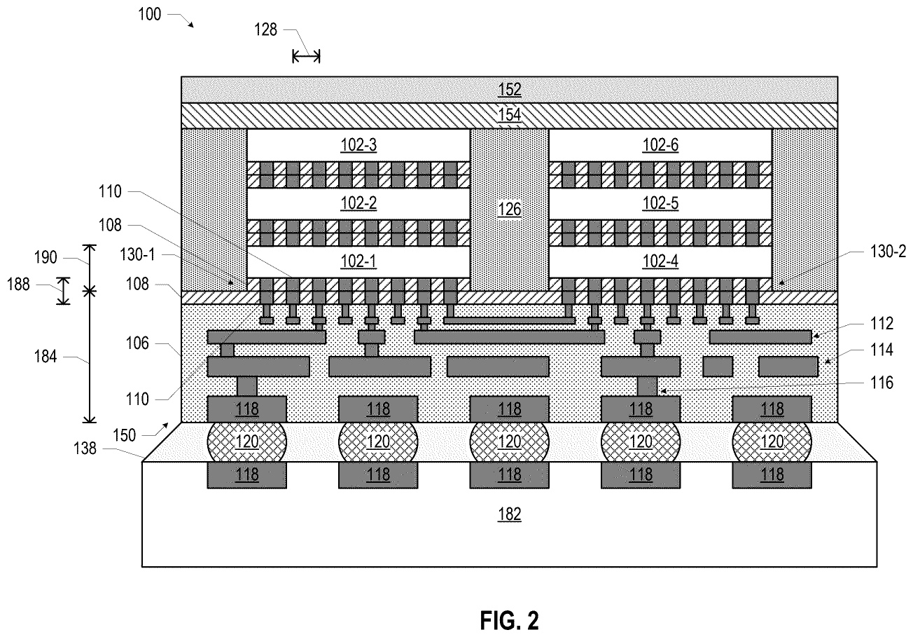

FIGS. 2-4 illustrate cross-sectional side views of the microelectronic assembly 100 with different types of interconnects between the dies 102-1, 102-2, and 102-3 of the stack.

Direct bonding has attracted considerable attraction recently for coupling microelectronic components (e.g., two dies, or a die and one of a package substrate, a circuit board, or an interposer). As used herein, the term “direct bonding” is used to include metal-to-metal bonding techniques (e.g., copper-to-copper bonding, or other techniques in which direct bonding contacts (DB contacts) of opposing direct bonding interfaces (DB interfaces) are brought into contact first, then subject to heat and compression) and hybrid bonding techniques (e.g., techniques in which direct bonding dielectric (DB dielectric) of opposing DB interfaces, possibly first subjected to prior surface activation, are brought into contact first, then subject to heat and sometimes compression, or techniques in which the DB contacts and the DB dielectric, possibly first subjected to prior surface activation, of opposing DB interfaces are brought into contact substantially simultaneously, and the subject to heat and sometimes compression). The materials of opposing DB dielectrics can be homogeneous (i.e., have substantially the same material composition) or non-homogeneous (i.e., have different material compositions). In such techniques, the DB contacts, and the DB dielectric at one DB interface (e.g., at a DB interface of a first microelectronic component) are brought into contact with the DB contacts and the DB dielectric at another DB interface (e.g., at a DB interface of a second microelectronic component), respectively, and elevated pressures and/or temperatures may be applied to cause the contacting DB contacts and/or the contacting DB dielectrics to bond. Direct bonding may provide significant advantages over conventional coupling techniques such as solder-based interconnects or wirebonds. Direct bonding interconnects may be capable of reliably conducting a higher current than other types of interconnects; for example, some conventional solder interconnects may form large volumes of brittle intermetallic compounds when current flows, and the maximum current provided through such interconnects may be constrained to mitigate mechanical failure.

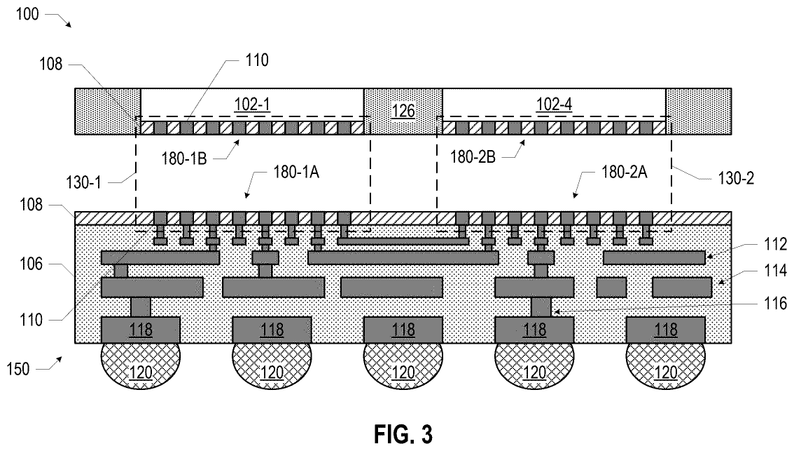

FIGS. 2 and 3 illustrate direct bonding between different stacked dies of the microelectronic assembly 100. In particular, FIG. 2 is a side, cross-sectional view of an example of the microelectronic assembly 100 of any of FIGS. 1A-1D with DBIs between adjacent dies 102 of a stack of dies, according to some embodiments, and FIG. 3 is a side, cross-sectional exploded view of a portion of the microelectronic assembly 100 of FIG. 2, according to some embodiments. The microelectronic assembly 100 may include a microelectronic component 150 coupled (e.g., directly electrical connected) to a die 102-1 (i.e., to the bottom die of any of the stacks of FIGS. 1A-1D) by a DB region 130-1. In various embodiments, the microelectronic component 150 may be one of an interposer, a package substrate, a circuit board, or a further die.

As illustrated in FIG. 3, the DB region 130-1 may include a DB interface 180-1A at the top surface of the microelectronic component 150, with the DB interface 180-1A including a set of conductive DB contacts 110 and a DB dielectric 108 around the DB contacts 110 of the DB interface 180-1A. The DB region 130-1 may also include a DB interface 180-1B at the bottom surface of the die 102-1, with the DB interface 180-1B including a set of DB contacts 110 and a DB dielectric 108 around the DB contacts 110 of the DB interface 180-1B. The DB contacts 110 of the DB interface 180-1A of the microelectronic component 150 may substantially align with the DB contacts 110 of the DB interface 180-1B of the die 102-1 so that, in the microelectronic assembly 100, the DB contacts 110 of the die 102-1 are in contact with the DB contacts 110 of the microelectronic component 150. In the microelectronic assembly 100 of FIG. 2, the DB interface 180-1A of the microelectronic component 150 may be bonded (e.g., electrically and mechanically) with the DB interface 180-1B of the die 102-1 to form the DB region 130-1 coupling the microelectronic component 150 and the die 102-1, as discussed further below. More generally, the DB regions 130 disclosed herein may include two complementary DB interfaces 180 bonded together; for ease of illustration, FIG. 2 omits the identification of the DB interfaces 180 to improve the clarity of the drawing.

As described above, the term “direct bonding” is used to include metal-to-metal bonding techniques such as copper-to-copper bonding, or other techniques in which the DB contacts 110 of opposing DB interfaces 180 are brought into contact first, then subject to heat and compression. The term is also used to include hybrid bonding techniques such as techniques in which the DB dielectric 108 of opposing DB interfaces 180, possibly first subjected to prior surface activation, are brought into contact and then subjected to heat and sometimes compression, or techniques in which the DB contacts 110 and the DB dielectric 108 of opposing DB interfaces 180, possibly first subjected to prior surface activation, are brought into contact substantially simultaneously, then subject to heat and sometimes compression. In all such techniques, the DB contacts 110 and the DB dielectric 108 at one DB interface 180 are brought into contact with, respectively, the DB contacts 110 and the DB dielectric 108 at another DB interface 180, and elevated pressures and/or temperatures may be applied to cause the contacting DB contacts 110 and/or the contacting DB dielectrics 108 to bond. In some embodiments, this bond may be achieved without the use of intervening solder or an anisotropic conductive material, while in some other embodiments, a thin cap of solder may be used in a DB interconnect (e.g., to accommodate planarity), and this solder may become an intermetallic compound in the DB region 130 during processing.

A DB dielectric 108 may include one or more dielectric materials, such as one or more inorganic dielectric materials. For example, a DB dielectric 108 may include silicon, carbon, and nitrogen (e.g., in the form of silicon carbon nitride); silicon and nitrogen (e.g., in the form of silicon nitride); silicon and oxygen (e.g., in the form of silicon oxide); carbon and oxygen (e.g., in the form of a carbon-doped oxide); silicon, oxygen, and nitrogen (e.g., in the form of silicon oxynitride); aluminum and oxygen (e.g., in the form of aluminum oxide); titanium and oxygen (e.g., in the form of titanium oxide); hafnium and oxygen (e.g., in the form of hafnium oxide); silicon, oxygen, carbon, and hydrogen (e.g., in the form of tetraethyl orthosilicate (TEOS)); zirconium and oxygen (e.g., in the form of zirconium oxide); niobium and oxygen (e.g., in the form of niobium oxide); tantalum and oxygen (e.g., in the form of tantalum oxide); and combinations thereof.

A DB contact 110 may include a pillar, a pad, or other structure. The DB contacts 110, although depicted in the accompanying drawings in the same manner at both DB interfaces 180 of a DB region 130, may have a same structure at both DB interfaces 180, or the DB contacts 110 at different DB interfaces 180 may have different structures. For example, in some embodiments, a DB contact 110 in one DB interface 180 may include a metal pillar (e.g., a copper pillar), and a complementary DB contact 110 in a complementary DB interface 180 may include a metal pad (e.g., a copper pad) recessed in a dielectric. A DB contact 110 may include one or more layers of electrically conductive materials such as copper, manganese, titanium, gold, silver, palladium, nickel, copper and aluminum (e.g., in the form of a copper aluminum alloy), tantalum (e.g., tantalum metal, or tantalum and nitrogen in the form of tantalum nitride), cobalt, cobalt and iron (e.g., in the form of a cobalt iron alloy), or any alloys of any of the foregoing (e.g., copper, manganese, and nickel in the form of manganin). In some embodiments, the DB dielectric 108 and the DB contacts 110 of a DB interface 180 may be manufactured using low-temperature deposition techniques (e.g., techniques in which deposition occurs at temperatures below 250 degrees Celsius, or below 200 degrees Celsius), such as low-temperature plasma-enhanced chemical vapor deposition (PECVD).

As shown in FIG. 2, the bottom dies of the stack, i.e., the dies 102-1 and 102-2 of the microelectronic assembly 100 of FIG. 2, are double-sided (or “multi-level,” or “omni-directional”) components in that they have conductive contacts on multiple surfaces (top and bottom). On the other hand, the top die of the stack, i.e., the die 102-3, may be a single-sided component in the sense that the die 102-3 only has conductive contacts (e.g., DB contacts 110) on a single (bottom) surface of the individual die 102. FIGS. 2 and 3 also illustrate a die 102-4 coupled (e.g., directly electrical connected) to the microelectronic component 150 by a DB region 130-2 (via the DB interfaces 180-2A and 180-2B, as shown in FIG. 3). While the dies 102-1, 102-2, and 102-3 are part of a first stack of dies 102 coupled to the microelectronic component 150, the die 102-4 may be a part of a second stack of dies 102 coupled to the microelectronic component 150. As shown in FIG. 2, the second stack of dies 102 may further include a die 102-5 stacked above the die 102-4, and a die 102-6 stacked above the die 102-5. As shown in FIG. 2, the bottom dies of the second stack, i.e., the dies 102-4 and 102-5 of the microelectronic assembly 100 of FIG. 2, are double-sided (or “multi-level,” or “omni-directional”) components, while the top die of the second stack, i.e., the die 102-6, may be a single-sided component. The dies 102 of the second stack may be a high-bandwidth memory dies stack, e.g., the second stack of the dies 102 of the microelectronic assembly 100 may implement main memory, in some embodiments. FIG. 2 illustrates that adjacent dies 102 in each stack are coupled (e.g., directly electrical connected) to one another by the DB contacts 110 surrounded by the DB dielectric 108. Descriptions provided with respect to the DBIs (e.g., the DB contacts 110 and the DB dielectric 108) between the microelectronic component 150 and the die 102-1 are applicable to the DBI between the microelectronic component 150 and the die 102-4, as well as to the DBIs between adjacent dies 102 of each stack shown.

Although FIG. 2 depicts a particular number of stacks of dies 102, and a particular number of dies 102 in each stack, coupled to the microelectronic component 150 by DB regions 130, this number and arrangement are simply illustrative. In various embodiments, a microelectronic assembly 100 may include any desired number and arrangement of dies 102 coupled to a microelectronic component 150 by DB regions 130, and a microelectronic assembly 100 may include any desired number and arrangement of one or more dies 102 coupled (e.g., directly electrical connected) to one or more other dies 102 by DB regions 130. Although a single reference numeral “108” is used to refer to the DB dielectrics of multiple different DB interfaces 180 (and different DB regions 130), this is simply for ease of illustration, and the DB dielectric 108 of different DB interfaces 180 (even within a single DB region 130) may have different materials and/or structures. Similarly, although a single reference numeral “110” is used to refer to the DB contacts of multiple different DB interfaces 180 (and different DB regions 130), this is simply for ease of illustration, and one or more of the DB contacts 110 described herein may have multiple layers of electrically conductive materials. Furthermore, the DB contacts 110 of different DB interfaces 180 (even within a single DB region 130) may have different materials and/or structures.

The microelectronic component 150 may include an insulating material 106 (e.g., one or more dielectric materials formed in multiple layers, as known in the art) and one or more conductive pathways 112 through the insulating material 106 (e.g., including lines 114 and/or vias 116, as shown). In some embodiments, the insulating material 106 of the microelectronic component 150 may be an organic material, such as polyimide or polybenzoxazole, or may include an organic polymer matrix (e.g., epoxide) with a filler material (that may be inorganic). In some such embodiments, the microelectronic component 150 may be referred to as an “organic interposer.” In some embodiments, the insulating material 106 of a microelectronic component 150 may be provided in multiple layers of organic buildup film. Organic microelectronic components 150 may be less expensive to manufacture than semiconductor-or glass-based interposers and may have electrical performance advantages due to the low dielectric constants of organic insulating materials 106 and the thicker lines that may be used (allowing for improved power delivery, signaling, and potential thermal benefits). Organic microelectronic components 150 may also have larger footprints than can be achieved for semiconductor-based interposers, which are limited by the size of the reticle used for patterning. Further, organic microelectronic components 150 may be subject to less restrictive design rules than those that constrain semiconductor-or glass-based interposers, allowing for the use of design features such as non-Manhattan routing (e.g., not being restricted to using one layer for horizontal interconnects and another layer for vertical interconnects) and the avoidance of TSVs such as through-silicon vias or through-glass vias (which may be limited in the achievable pitch, and may result in less desirable power delivery and signaling performance). Conventional IC packages including an organic interposer have been limited to solder-based attach technologies, which may have a lower limit on the achievable pitch that precludes the use of conventional solder-based interconnects to achieve the fine pitches desired for next generation devices. Utilizing an organic microelectronic component 150 in a microelectronic assembly 100 as disclosed herein may leverage these advantages of organic interposers in combination with the ultra-fine pitch (e.g., the pitch 128 discussed below) achievable by direct bonding (and previously only achievable when using semiconductor-based interposers), and thus may support the design and fabrication of large and sophisticated die complexes that can achieve packaged system competition performance and capabilities not enabled by conventional approaches.

In other embodiments, the insulating material 106 of the microelectronic component 150 may include a fire retardant grade 4 material (FR-4), bismaleimide triazine (BT) resin, or low-k or ultra low-k dielectric (e.g., carbon-doped dielectrics, fluorine-doped dielectrics, and porous dielectrics). When the microelectronic component 150 is formed using standard PCB processes, the insulating material 106 may include FR-4, and the conductive pathways 112 in the microelectronic component 150 may be formed by patterned sheets of copper separated by buildup layers of the FR-4. In some such embodiments, the microelectronic component 150 may be referred to as a “package substrate” or a “circuit board.”

In some embodiments, one or more of the conductive pathways 112 in the microelectronic component 150 may extend between a conductive contact at the top surface of the microelectronic component 150 (e.g., one of the DB contacts 110) and a conductive contact 118 at the bottom surface of the microelectronic component 150. In some embodiments, one or more of the conductive pathways 112 in the microelectronic component 150 may extend between different conductive contacts at the top surface of the microelectronic component 150 (e.g., between different DB contacts 110 potentially in different DB regions 130, as discussed further below). In some embodiments, one or more of the conductive pathways 112 in the microelectronic component 150 may extend between different conductive contacts 118 at the bottom surface of the microelectronic component 150.

In some embodiments, a microelectronic component 150 may only include conductive pathways 112, and may not contain active or passive circuitry. In other embodiments, a microelectronic component 150 may include active or passive circuitry (e.g., transistors, diodes, resistors, inductors, and capacitors, among others). In some embodiments, a microelectronic component 150 may include one or more device layers including transistors.

Although FIGS. 2 and 3 (and others of the accompanying drawings) illustrate a specific number and arrangement of conductive pathways 112 in the microelectronic component 150, these are simply illustrative, and any suitable number and arrangement may be used. The conductive pathways 112 disclosed herein (e.g., including lines 114 and/or vias 116) may be formed of any appropriate conductive material, such as copper, silver, nickel, gold, aluminum, other metals or alloys, or combinations of materials, for example.

In some embodiments, a die 102 may include an insulating material. The insulating material of a die 102 may include silicon dioxide, silicon nitride, oxynitride, polyimide materials, glass-reinforced epoxy matrix materials, or a low-k or ultra low-k dielectric (e.g., carbon-doped dielectrics, fluorine-doped dielectrics, porous dielectrics, organic polymeric dielectrics, photo-imageable dielectrics, and/or benzocyclobutene-based polymers). In some further embodiments, the insulating material of a die 102 may include a semiconductor material, such as silicon, germanium, or a III-V material (e.g., gallium nitride), and one or more additional materials. For example, an insulating material of a die 102 may include silicon oxide or silicon nitride. The conductive pathways in a die 102 may include conductive lines and/or conductive vias and may connect any of the conductive contacts in the die 102 in any suitable manner (e.g., connecting multiple conductive contacts on a same surface or on different surfaces of the die 102). Example structures that may be included in the dies 102 disclosed herein are discussed below with reference to FIG. 20. In particular, a die 102 may include active and/or passive circuitry (e.g., transistors, diodes, resistors, inductors, and capacitors, among others). In some embodiments, a die 102 may include one or more device layers including transistors. When a die 102 includes active circuitry, power and/or ground signals may be routed to/from a die 102 through a DB region 130 (e.g., routed through the microelectronic component 150 and/or routed to/from other dies 102). In some embodiments, a die 102 may take the form of any of the embodiments of the microelectronic component 150 herein. Conversely, in some embodiments, the microelectronic component 150 shown in FIG. 2, or portions thereof, may be another die 102 or portions of another die 102.

Additional components (not shown), such as surface-mount resistors, capacitors, and/or inductors, may be disposed on the top surface or the bottom surface of the microelectronic component 150, or embedded in the microelectronic component 150. The microelectronic assembly 100 of FIG. 2 also includes a support component 182 coupled to the microelectronic component 150. In the particular embodiment of FIG. 2, the support component 182 includes conductive contacts 118 that are electrically coupled to complementary conductive contacts 118 of the microelectronic component 150 by intervening solder 120 (e.g., solder balls in a ball grid array (BGA) arrangement), but any suitable interconnect structures may be used (e.g., pins in a pin grid array arrangement, lands in a land grid array arrangement, pillars, pads and pillars, etc.). The solder 120 utilized in the microelectronic assemblies 100 disclosed herein may include any suitable materials, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, the couplings between the microelectronic component 150 and the support component 182 may be referred to as second-level interconnects (SLI) or multi-level interconnects (MLI).

In some embodiments, the microelectronic component 150 may be an interposer or another die, and the support component 182 may be a package substrate (e.g., may be manufactured using PCB processes, as discussed above). In some embodiments, the support component 182 may be a circuit board (e.g., a motherboard), and may have other components attached to it (not shown). The support component 182 may include conductive pathways and other conductive contacts (not shown) for routing power, ground, and signals through the support component 182, as known in the art. In some embodiments, the support component 182 may include another IC package, an interposer, or any other suitable component. An underfill material 138 may be disposed around the solder 120 coupling the microelectronic component 150 to the support component 182. In some embodiments, the underfill material 138 may include an epoxy material.

In some embodiments, the support component 182 may be a lower density component, while the microelectronic component 150 and/or the dies 102 may be higher density components. As used herein, the term “lower density” and “higher density” are relative terms indicating that the conductive pathways (e.g., including conductive lines and conductive vias) in a lower density component are larger and/or have a greater pitch than the conductive pathways in a higher density component. In some embodiments, a die 102 may be a higher density component, and a microelectronic component 150 may be a lower density component. In some embodiments, a higher density component may be manufactured using a dual-damascene or single damascene process (e.g., when the higher density component is a die), while a lower density component may be manufactured using a semi-additive or modified semi-additive process (with small vertical interconnect features formed by advanced laser or lithography processes) (e.g., when the lower density component is a package substrate or an interposer). In some other embodiments, a higher density component may be manufactured using a semi-additive or modified semi-additive process (e.g., when the higher density component is a package substrate or an interposer), while a lower density component may be manufactured using a semi-additive or a subtractive process (using etch chemistry to remove areas of unwanted metal, and with coarse vertical interconnect features formed by a standard laser process) (e.g., when the lower density component is a PCB).

The microelectronic assembly 100 of FIG. 2 may also include a mold material 126. The mold material 126 may extend around one or more of the dies 102 on the microelectronic component 150. In some embodiments, the mold material 126 may extend between multiple dies 102 on the microelectronic component 150 and around the DB regions 130. In some embodiments, the mold material 126 may extend above one or more of the dies 102 on a microelectronic component 150. The mold material 126 may be an insulating material, such as an appropriate epoxy material. The mold material 126 may be selected to have a coefficient of thermal expansion (CTE) that may mitigate or minimize the stress between the dies 102 and the microelectronic component 150 arising from uneven thermal expansion in the microelectronic assembly 100. In some embodiments, the CTE of the mold material 126 may have a value that is intermediate to the CTE of the microelectronic component 150 (e.g., the CTE of the insulating material 106 of the microelectronic component 150) and a CTE of the dies 102. In some embodiments, the mold material 126 used in a microelectronic assembly 100 may be selected at least in part for its thermal properties. For example, one or more mold materials 126 used in a microelectronic assembly 100 may have low thermal conductivity (e.g., conventional mold compounds) to retard heat transfer, or may have high thermal conductivity (e.g., mold materials including metal or ceramic particles with high thermal conductivity, such as copper, silver, diamond, silicon carbide, aluminum nitride, and boron nitride, among others) to facilitate heat transfer. Any of the mold materials 126 referred to herein may include one or more different materials with different material compositions.

The microelectronic assembly 100 of FIG. 2 may also include a TIM 154. The TIM 154 may include a thermally conductive material (e.g., metal particles) in a polymer or other binder. The TIM 154 may be a thermal interface material paste or a thermally conductive epoxy (which may be a fluid when applied and may harden upon curing, as known in the art). The TIM 154 may provide a path for heat generated by the dies 102 to readily flow to the heat transfer structure 152, where it may be spread and/or dissipated. Some embodiments of the microelectronic assembly 100 of FIG. 2 may include a sputtered metallization (not shown) across the top surfaces of the mold material 126 and the dies 102; the TIM 154 (e.g., a solder TIM) may be disposed on this metallization.

The microelectronic assembly 100 of FIG. 2 may also include a heat transfer structure 152. The heat transfer structure 152 may be used to move heat away from one or more of the dies 102 (e.g., so that the heat may be more readily dissipated). The heat transfer structure 152 may include any suitable thermally conductive material (e.g., metal, appropriate ceramics, etc.), and may include any suitable features (e.g., a heat spreader, a heat sink including fins, a cold plate, etc.). In some embodiments, a heat transfer structure 152 may be or may include an integrated heat spreader (IHS).

The elements of a microelectronic assembly 100 may have any suitable dimensions. Only a subset of the accompanying drawings are labeled with reference numerals representing dimensions, but this is simply for clarity of illustration, and any of the microelectronic assemblies 100 disclosed herein may have components having the dimensions discussed herein. In some embodiments, the thickness 184 of the microelectronic component 150 may be between 20 microns and 200 microns. In some embodiments, the thickness 188 of a DB region 130 may be between 50 nanometers and 8 microns, e.g., between 100 nanometers and 6 microns or between 100 nanometers and 5 microns. Because the thickness 188 includes a DB dielectric 108 and DB contacts 110 on each of the two sides of DB interfaces 180 being bonded, this means that a thickness of the DB dielectric 108 for each of the sides being bonded, and, correspondingly, a height of the DB contacts 110, may be about half of the thickness 188. In some embodiments, a thickness 190 of a die 102 may be between 5 microns and 800 microns. In some embodiments, a pitch 128 of the DB contacts 110 in a DB region 130 may be less than 20 microns (e.g., between 0.1 microns and 20 microns).

A number of elements are illustrated in FIG. 2 as included in the microelectronic assembly 100, but a number of these elements may not be present in a microelectronic assembly 100. For example, in various embodiments, the heat transfer structure 152, the thermal interface material (TIM) 154, the mold material 126, the second stack of dies 102-4, 102-5, and 102-6, or any individual dies 102 within the second stack, the underfill material 138, and/or the support component 182 may not be included. In another example, in some embodiments, the die 102-1 of the microelectronic assembly 100 may be coupled to another die 102 by a DB region 130, but the microelectronic component 150 of FIG. 2, and the associated DB region 130-1 coupling the die 102-1 to the microelectronic component 150 may not be included. In such embodiments, descriptions of portions of the DB regions 130 provided for the microelectronic component 150, such as descriptions of the DB interfaces 180 or DB contacts 110 of the microelectronic component 150 provided with reference to FIG. 3, are applicable to DB regions 130 between two dies 102.

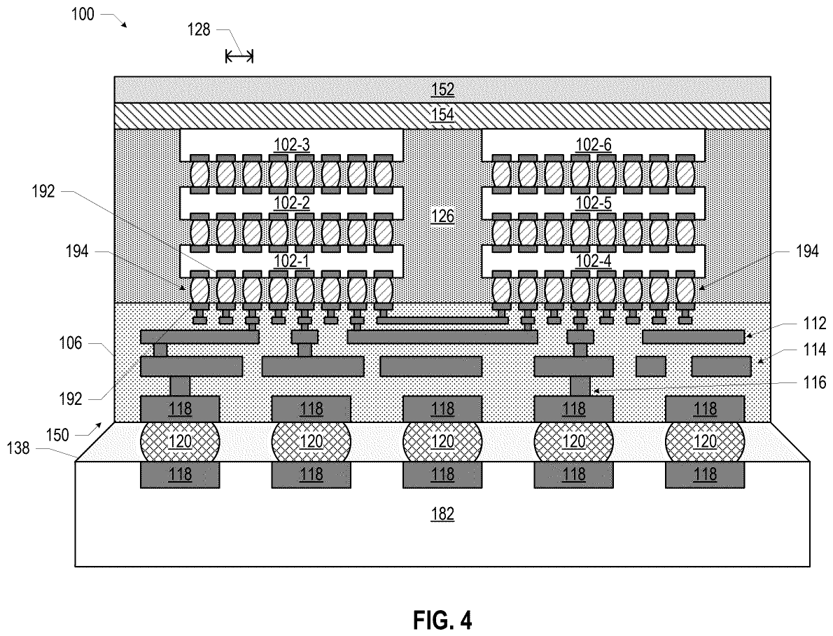

FIG. 4 is a side, cross-sectional view of an example of the microelectronic assembly 100 of any of FIGS. 1A-1D with solder-based DTD interconnects between adjacent dies 102 of a stack of dies, according to some embodiments. The microelectronic assembly 100 of FIG. 4 is similar to that shown in FIG. 2 in that many of the elements of the microelectronic assembly 100 of FIG. 2 are included in the microelectronic assembly 100 of FIG. 4. The discussion of these elements is not repeated for FIG. 4 (and subsequent drawings), and any of these elements may take any of the forms disclosed herein. Where FIG. 2 and FIG. 4 differ is that the microelectronic assembly 100 of FIG. 4 does not include the DBIs in the form of the DB contacts 110 and the DB dielectric 108 as described for FIGS. 2 and 3. In their place, the microelectronic assembly 100 of FIG. 4 includes conductive contacts 192 and solder-based DTD interconnects 194.

As shown in FIG. 4, the top surface of the microelectronic component 150 may include a set of conductive contacts 192, and the bottom surface of the die 102-1 may include a set of conductive contacts 192, and the conductive contacts 192 at the bottom surface of the die 102-1 may be electrically and mechanically coupled to the conductive contacts 192 at the top surface of the microelectronic component 150 by the DTD interconnects 194. In some embodiments, one or more of the conductive pathways in the microelectronic component 150 may extend between a conductive contact 192 at the top surface of the microelectronic component 150 and a conductive contact 118 at the bottom surface of the microelectronic component 150.

The DTD interconnects 194 disclosed herein may take any suitable form. In some embodiments, a set of DTD interconnects 194 may include solder (e.g., solder bumps or balls that are subject to a thermal reflow to form the DTD interconnects 194). DTD interconnects 194 that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTD interconnects 194 may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression. In some embodiments, the DTD interconnects 194 may include small conductive bumps or pillars (e.g., copper bumps or pillars) attached to the conductive contacts 192 by solder. In some embodiments, the DTD interconnects 194 between adjacent dies 102 of a stack of dies of the microelectronic assembly 100 may have a finer pitch than the DTD interconnects 194 between the microelectronic component 150 and the bottom die 102 of a stack (e.g., the die 102-1 or the die 102-4 of FIG. 4). In some embodiments, the DTD interconnects 194 between the bottom die 102 of a stack and the microelectronic component 150 may have a pitch between 80 microns and 300 microns, while the DTD interconnects 194 between individual adjacent dies 102 of a stack of dies of the microelectronic assembly 100 may have a pitch between 7 microns and 100 microns. In some embodiments, the DTD interconnects 194 between individual adjacent dies 102 of a stack of dies of the microelectronic assembly 100 may have too fine a pitch to couple to the microelectronic component 150 directly. In some embodiments, the DTD interconnects 194 between individual adjacent dies 102 of a stack of dies of the microelectronic assembly 100 may be used as data transfer lanes, while the DTD interconnects 194 between the bottom die 102 of a stack and the microelectronic component 150 may be used for power and ground lines, among others. In some embodiments, some or all of the DTD interconnects 194 between individual adjacent dies 102 of a stack of dies of the microelectronic assembly 100 may be solder interconnects that include a solder with a higher melting point than a solder included in some or all of the DTD interconnects 194 between the bottom die 102 of a stack and the microelectronic component 150. For example, when the DTD interconnects 194 between individual adjacent dies 102 of a stack of dies of the microelectronic assembly 100 are formed before the DTD interconnects 194 between the bottom die 102 of a stack and the microelectronic component 150 are formed, solder-based DTD interconnects 194 between individual adjacent dies 102 of a stack of dies of the microelectronic assembly 100 may use a higher-temperature solder (e.g., with a melting point above 200 degrees Celsius), while the DTD interconnects 194 between the bottom die 102 of a stack and the microelectronic component 150 may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth) or tin, silver, and bismuth. In some embodiments, a lower-temperature solder may include indium, indium and tin, or gallium.

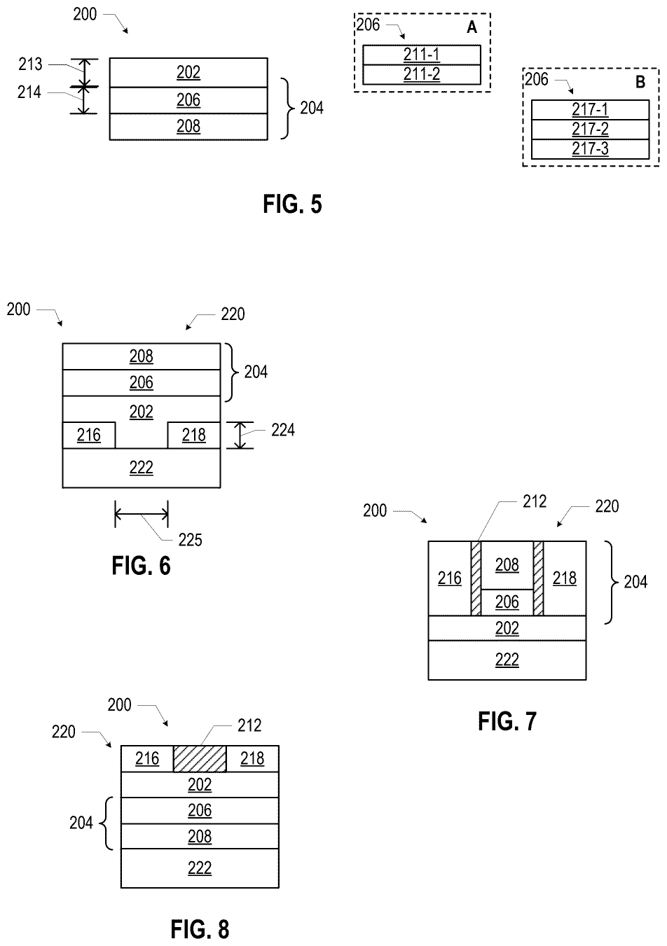

The tags of the tags die 103-1, the logic transistors of the compute die 103-2, and memory cells of the cache memory die 103-3 may be implemented using transistors of any suitable architecture and topology. Some examples of transistors that may be included in the microelectronic assembly 100 are described with reference to FIGS. 5-15B.

FIG. 5 is a cross-sectional side view of an IC structure 200 including a channel material 202, and further including a transistor gate stack 204 (also referred to as a “transistor gate stack 204” herein), in accordance with various embodiments. The transistor gate stack 204 may include a gate electrode material 208, and a gate insulator 206 disposed between the channel material 202 and the gate electrode material 208.

In various embodiments, the channel material 202 may be composed of semiconductor material systems including, for example, n-type or p-type materials systems. In some embodiments, the channel material 202 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the channel material 202 may include a combination of semiconductor materials. In some embodiments, the channel material 202 may include a monocrystalline semiconductor, such as silicon (Si) or germanium (Ge). In some embodiments, the channel material 202 may be formed of a compound semiconductor with a first sub-lattice of at least one element from group III of the periodic table (e.g., Al, Ga, In), and a second sub-lattice of at least one element from group V of the periodic table (e.g., nitrogen (N) or phosphorous (P)). In other embodiments, the channel material 202 may be formed of a compound semiconductor with a first sub-lattice of at least one element from group II of the periodic table, and a second sub-lattice of at least one element from group VI of the periodic table.

For some example n-type transistor embodiments (i.e., for the embodiments where a transistor with the channel material 202 is an n-type metal-oxide-semiconductor (NMOS) transistor), the channel material 202 may include a III-V material having a relatively high electron mobility, such as, but not limited to InGaAs, InP, InSb, and InAs. For some such embodiments, the channel material 202 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example p-type transistor embodiments (i.e., for the embodiments where a transistor with the channel material 202 is a p-type metal-oxide-semiconductor (PMOS) transistor), the channel material 202 may advantageously be a group IV material having a high hole mobility, such as, but not limited to Ge or a Ge-rich SiGe alloy. For some example embodiments, the channel material 202 may have a Ge content between 0.6 and 0.9, and advantageously may be at least 0.7.

In some embodiments, any of the transistors of microelectronic assemblies with tags disintegrated from cache memory may be thin-film transistors (TFT) (e.g., any of the transistors illustrated in FIGS. 6-13). A TFT is a special kind of a field-effect transistor made by depositing a thin film of an active semiconductor material, as well as a dielectric layer and metallic contacts, over a supporting layer that may be a non-conducting layer and a non-semiconductor layer. At least a portion of the active semiconductor material forms a channel of the TFT. This is different from conventional, non-TFT, front-end of line (FEOL) logic transistors where the active semiconductor channel material is typically a part of a semiconductor substrate, e.g., a part of a silicon wafer. Using TFTs may provide several advantages and enable unique architectures that were not possible with conventional, FEOL logic transistors. For example, one advantage is that a TFT may have substantially lower leakage than a logic transistor. Therefore, using TFTs as access transistors of memory cells may allow relaxing the demands on the large capacitance placed on the capacitors of DRAM cells. In other words, using a lower leakage TFT in a DRAM cell allows the DRAM cell to use a capacitor with lower capacitance and smaller aspect ratio while still meeting the same data retention requirements of other approaches, alleviating the scaling challenges of capacitors.

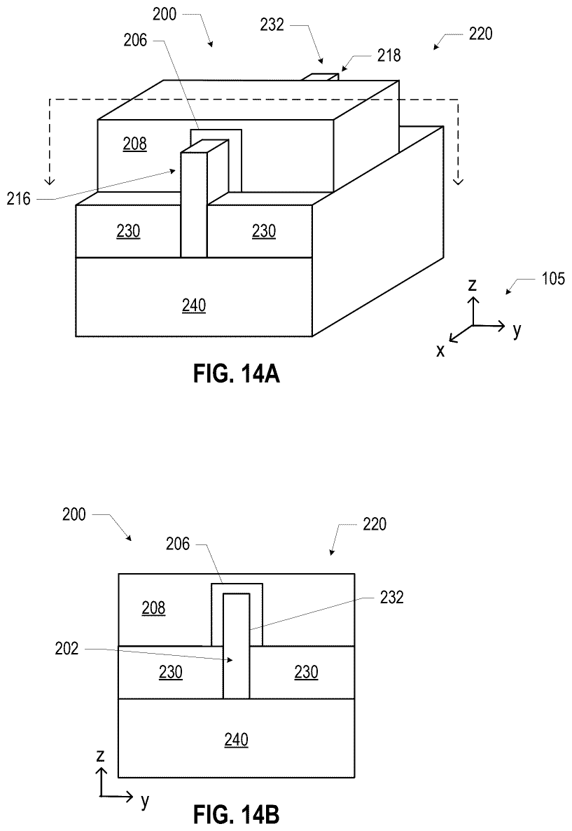

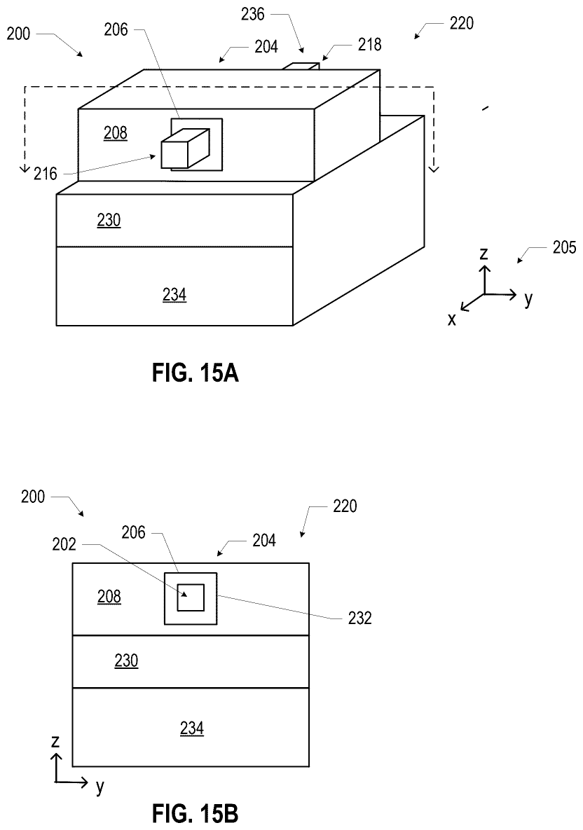

Additionally or alternatively to TFTs, any of the transistors of microelectronic assemblies with tags disintegrated from cache memory may be implemented using layer transfer to form transistors in one or more back-end of line (BEOL) layers of IC structures (such transistors may be referred to as “back-end transistors”). Layer transfer may include epitaxially growing a layer of a highly crystalline semiconductor material on another substrate and then transferring the layer, or a portion thereof, to embed it in the one or more BEOL layers provided over a second substrate. Channel regions of back-end transistors then include at least portions of such transferred semiconductor material layer. Performing layer transfer may advantageously allow forming non-planar transistors, such as FinFETs or nanowire/nanoribbon transistors (e.g., as any of the transistors 220 of FIGS. 14A-14B or FIGS. 15A-15B, or as any combination of such transistors) in the one or more BEOL layers. In some embodiments, transistors, or portions thereof (e.g., S/D regions) may be formed on the first substrate (i.e., on the substrate on which a layer of a highly crystalline semiconductor material is grown) before the layer transfer takes place, and then a layer with such transistors, or portions thereof, is transferred.

Layer transfer approach for providing transistors may be particularly suitable for forming transistors with channel regions formed of substantially single-crystalline semiconductor materials. On the other hand, TFTs may be seen as an example of a monolithic integration approach because the semiconductor materials for the channel regions are deposited in one or more BEOL layers of an IC structure, as opposed to being epitaxially grown elsewhere and then transferred, which may be particularly suitable for forming transistors with channels formed of polycrystalline, polymorphous, or amorphous semiconductor materials, or various other thin-film channel materials. Whether a semiconductor material of the channel material 202 for a given transistors (e.g., a back-end transistor) has been provided by monolithic integration approach or by layer transfer can be identified by inspecting grain size of the channel material 202. An average grain size of the channel material 202 being between about 0.5 and 1 millimeters (in which case the material may be polycrystalline) or smaller than about 0.5 millimeter (in which case the material may be polymorphous) may be indicative of the channel material 202 having been deposited in the one or more BEOL layers of the device (i.e., monolithic integration approach), e.g., to form a TFT. On the other hand, an average grain size of the channel material 202 being equal to or greater than about 1 millimeter (in which case the material may be a single-crystal material) may be indicative of the channel material 202 having been included in the one or more BEOL layers using layer transfer.

In some embodiments, the gate insulator 206 may include a programmable insulator material, e.g., may include a hysteretic material or a hysteretic arrangement, which, together, may be referred to as a “hysteretic element.” For example, in some embodiments, the gate insulator 206 may include ferroelectric (FE) and/or antiferroelectric (AFE) materials as hysteretic materials. In some embodiments, the gate insulator 206 may include layers of different materials arranged in a stack to exhibit charge-trapping phenomena, as an example of a hysteretic arrangement.

A FE or an AFE material is a material that exhibits, over some range of temperatures, spontaneous electric polarization, i.e., displacement of positive and negative charges from their original position, where the polarization can be reversed or reoriented by application of an electric field. In particular, an AFE material is a material that can assume a state in which electric dipoles from the ions and electrons in the material may form a substantially ordered (e.g., substantially crystalline) array, with adjacent dipoles being oriented in opposite (antiparallel) directions (i.e., the dipoles of each orientation may form interpenetrating sub-lattices, loosely analogous to a checkerboard pattern), while a FE material is a material that can assume a state in which all of the dipoles point in the same direction. Because the displacement of the charges in FE and AFE materials can be maintained for some time even in the absence of an electric field, including such materials in a gate insulator 206 may be used to realize a hysteretic gate. Because the current state of the electric dipoles in FE and AFE materials depends on the previous state, such materials are hysteretic materials.

A stack of alternating layers of materials that is configured to exhibit charge-trapping is an example of a hysteretic arrangement. Such a stack may include as little as two layers of materials, one of which is a charge-trapping layer (i.e., a layer of a material configured to trap charges when a volage is applied across the material) and the other one of which is a tunnelling layer (i.e., a layer of a material through which the charge is to be tunneled to the charge-trapping layer). The tunnelling layer may include an insulator material such as a material that includes silicon and oxygen (e.g., silicon oxide), or any other suitable insulator. The charge-trapping layer may include a metal or a semiconductor material that is configured to trap charges. For example, a material that includes silicon and nitrogen (e.g., silicon nitride) may be used in/as a charge-trapping layer. Because the trapped charges may be kept in a charge-trapping arrangement for some time even in the absence of an electric field, including such arrangements in a gate insulator 206 may be used to realize a hysteretic gate. Because the presence and/or the amount of trapped charges in a charge-trapping arrangement depends on the previous state, such arrangements are hysteretic arrangements.

In some embodiments, the hysteretic element of the gate insulator 206 may be provided as a layer of a FE or an AFE material. Such an FE/AFE material may include one or more materials that can exhibit sufficient FE/AFE behavior even at thin dimensions, e.g., such as an insulator material at least about 5%, e.g., at least about 7% or at least about 10%, of which is in an orthorhombic phase and/or a tetragonal phase (e.g., as a material in which at most about 95-90% of the material may be amorphous or in a monoclinic phase). For example, such materials may be based on hafnium and oxygen (e.g., hafnium oxides), with various dopants added to ensure sufficient amount of an orthorhombic phase or a tetragonal phase. Some examples of such materials include materials that include hafnium, oxygen, and zirconium (e.g., hafnium zirconium oxide (HfZrO, also referred to as HZO)), materials that include hafnium, oxygen, and silicon (e.g., silicon-doped (Si-doped) hafnium oxide), materials that include hafnium, oxygen, and germanium (e.g., germanium-doped (Ge-doped) hafnium oxide), materials that include hafnium, oxygen, and aluminum (e.g., aluminum-doped (Al-doped) hafnium oxide), and materials that include hafnium, oxygen, and yttrium (e.g., yttrium-doped (Y-doped) hafnium oxide). However, in other embodiments, any other materials which exhibit FE/AFE behavior at thin dimensions may be used as the hysteretic element and are within the scope of the present disclosure.

In other embodiments, the hysteretic element of the gate insulator 206 may be provided as a stack of alternating layers of materials that can trap charges. In some such embodiments, the stack may be a two-layer stack as shown in FIG. 5 within the dashed contour of an inset A, illustrating that the gate insulator 206 may include a first layer 211-1 and a second layer 211-2, where one of the first layer 211-1 and the second layer 211-2 is a charge-trapping layer, and the other one of the first layer 211-1 and the second layer 211-2 is a tunnelling layer. The tunnelling layer may include an insulator material such as a material that includes silicon and oxygen (e.g., silicon oxide), or any other suitable insulator. The charge-trapping layer may include an electrically conductive material such as a metal, or a semiconductor material. In some embodiments, the charge-trapping layer may include a material that includes silicon and nitrogen (e.g., silicon nitride). In general, any material that has defects that can trap charge may be used in/as a charge-trapping layer. Such defects are very detrimental to operation of logic devices and, therefore, typically, deliberate steps need to be taken to avoid presence of the defects. However, for the gate insulator 206 being a hysteretic arrangement, such defects are desirable because charge-trapping may be used to represent different states of the gate insulator 206.

In some embodiments of the hysteretic element of the gate insulator 206 being provided as a stack of alternating layers of materials that can trap charges, the stack may be a three-layer stack where an insulator material is provided on both sides of a charge-trapping layer. The three-layer stack is shown in FIG. 5 within the dashed contour of an inset B, illustrating that the gate insulator 206 may include a first layer 217-1, a second layer 217-2, and a third layer 217-3, where the second layer 217-2 may be a charge-trapping layer, while the first layer 217-1 and the third layer 217-3 may be insulator material layers. In such embodiments, a layer of an insulator material on one side of the second layer 217-2 that is the charge-trapping layer (e.g., the insulator material of the first layer 217-1) may be referred to as a “tunnelling layer” while a layer of an insulator material on the other side of the charge-trapping layer (e.g., the insulator material of the third layer 217-3) may be referred to as a “field layer.”

In various embodiments of the hysteretic element of the gate insulator 206 being provided as a stack of alternating layers of materials that can trap charges, a thickness of each layer the stack may be between about 0.5 and 10 nanometers, including all values and ranges therein, e.g., between about 0.5 and 5 nanometers. In some embodiment of a three-layer stack, a thickness of each layer of the insulator material may be about 0.5 nanometers, while a thickness of the charge-trapping layer may be between about 1 and 8 nanometers, e.g., between about 2.5 and 7.5 nanometers, e.g., about 5 nanometers. In some embodiments, a total thickness of the hysteretic element provided as a stack of alternating layers of materials that can trap charges (i.e., a hysteretic arrangement) may be between about 1 and 10 nanometers, e.g., between about 2 and 8 nanometers, e.g., about 6 nanometers.

In some embodiments, the gate insulator 206 may include a dielectric material that is not a FE or an AFE material. In such embodiments, the gate insulator 206 may include one or more high-k dielectrics. In some embodiments, the high-k dielectric may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate insulator 206 may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In some embodiments, an annealing process may be carried out on the gate insulator 206 during fabrication of the transistors to improve the quality of the gate insulator 206. The gate insulator 206 that is not a FE or an AFE material may have a thickness that may, in some embodiments, be between about 0.5 nanometers and 3 nanometers, including all values and ranges therein (e.g., between about 1 and 3 nanometers, or between about 1 and 2 nanometers), although, in other embodiments, the thickness of the gate insulator 206 may be greater than 3 nanometers.

The gate electrode material 208 may include at least one p-type work function metal or n-type work function metal, depending on whether the transistor gate stack 204 is to be included in a PMOS transistor or an NMOS transistor (e.g., any of the transistors 220 discussed below). For a PMOS transistor, metals that may be used for the gate electrode material 208 may include, but are not limited to, ruthenium, palladium, platinum, cobalt, nickel, and conductive metal oxides (e.g., ruthenium oxide). For an NMOS transistor, metals that may be used for the gate electrode material 208 include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide). In some embodiments, the gate electrode material 208 may include a stack of two or more metal layers, where one or more metal layers are work function metal layers and at least one metal layer is a fill metal layer. Further metal layers may be included for other purposes, such as to act as a barrier layer.

In some embodiments, the transistor gate stack 204 may be surrounded by a gate spacer, not shown in FIG. 5. Such a gate spacer would be configured to provide separation between the transistor gate stack 204 and source/drain (S/D) contacts of the transistor and could be made of a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass. A gate spacer may include pores or air gaps to further reduce its dielectric constant.

The dimensions of the elements of an IC structure 200 may take any suitable values. For example, the channel material 202 may have a thickness 213. In some embodiments, the thickness 213 may be between about 5 nanometers and 100 nanometers, e.g., between about 5 nanometers and 30 nanometers, or between about 5 nanometers and 10 nanometers. The gate insulator 206 may have a thickness 214. In some embodiments, the thickness 214 may be between about 0.5 nanometers and 3 nanometers, e.g., between about 1 nanometer and 3 nanometers, or between about 1 nanometer and 2 nanometers. In other embodiments, the thickness 214 may be as described above with reference to hysteretic elements.

The transistor gate stack 204 may be included in any suitable transistor structure. For example, FIGS. 6-10 are cross-sectional side views of example single-gate transistors 220 including a transistor gate stack 204, FIGS. 11-13 are cross-sectional side views of example double-gate transistors 220 including a transistor gate stack 204, FIGS. 14A and 14B are perspective and cross-sectional side views, respectively, of an example tri-gate transistor 220 including a transistor gate stack 204, and FIGS. 15A and 15B are perspective and cross-sectional side views, respectively, of an example all-around gate transistor 220 including a transistor gate stack 204, in accordance with various embodiments.

The transistors 220 illustrated in FIGS. 6-15 do not represent an exhaustive set of transistor structures in which a transistor gate stack 204 with a gate insulator 206 may be included, but provide examples of such structures. Note that FIGS. 6-15 are intended to show relative arrangements of the components therein, and the transistors 220 may include other components that are not illustrated (e.g., electrical contacts to the gate electrode materials 208, etc.). Any of the components of the transistors 220 discussed below with reference to FIGS. 6-15 may take the form of any of the embodiments of those components discussed above with reference to FIG. 5. Additionally, although various components of the transistors 220 are illustrated in FIGS. 6-15 as being planar rectangles or formed of rectangular solids, this is simply for ease of illustration, and embodiments of these transistors 220 may be curved, rounded, or otherwise irregularly shaped as dictated by the manufacturing processes used to fabricate the transistors 220. The transistors 220 of FIGS. 6-7 may be referred to as “top gate” transistors, while the transistors 220 of FIGS. 8-10 may be referred to as “bottom gate” transistors. Similarly, the transistors 220 of FIGS. 6 and 10 may be referred to as “bottom contact” transistors, while the transistors 220 of FIGS. 7-9 may be referred to as “top contact” transistors.

FIG. 6 depicts a transistor 220 including a transistor gate stack 204 and having a single “top” gate provided by the gate insulator 206 and the gate electrode material 208. In the embodiment of FIG. 6, the transistor gate stack 204 is shown as disposed above a support 222. The support 222 may be any structure on which the transistor gate stack 204, or other elements of the transistor 220, is disposed. In some embodiments, the support 222 may include a semiconductor, such as silicon. In some embodiments, the support 222 may include an insulating layer, such as an oxide isolation layer. For example, in the embodiments of FIGS. 6 and 7, the support 222 may include a semiconductor material and an interlayer dielectric (ILD) disposed between the semiconductor material and the S/D contact 216, the channel material 202, and the S/D contact 218, to electrically isolate the semiconductor material of the support 222 from the S/D contact 216, the channel material 202, and the S/D contact 218 (and thereby mitigate the likelihood that a conductive pathway will form between the S/D contact 216 and the S/D contact 218 through the support 222). Examples of ILDs that may be included in a support 222 in some embodiments may include silicon oxide, silicon nitride, aluminum oxide, and/or silicon oxynitride. Any suitable ones of the embodiments of the support 222 described with reference to FIG. 6 may be used for the supports 222 of others of the transistors 220 disclosed herein.

As noted above, the transistor 220 may include an S/D contact 216 and an S/D contact 218 disposed on the support 222, with the channel material 202 disposed between the S/D contact 216 and the S/D contact 218 so that at least some of the channel material 202 is coplanar with at least some of the S/D contact 216 and the S/D contact 218. The S/D contact 216 and the S/D contact 218 may be the S/D contacts 1624 and may be coupled (e.g., directly electrical connected) to S/D regions 1620 described below with reference to FIG. 20. The S/D contact 216 and the S/D contact 218 may have a thickness 224. In some embodiments, the thickness 224 may be less than the thickness 213 (as illustrated in FIG. 6, with the S/D contact 216 and the S/D contact 218 each disposed between some of the channel material 202 and the support 222), while in other embodiments, the thickness 224 may be equal to the thickness 213. In some embodiments, the channel material 202, and any one or more of the gate insulator 206 and the gate electrode material 208 may conform around the S/D contact 216 and/or the S/D contact 218. The S/D contact 216 and the S/D contact 218 may be spaced apart by a distance 225 that is the gate length of the transistor 220. In some embodiments, the gate length may be between 20 nanometers and 30 nanometers (e.g., between 22 nanometers and 28 nanometers, or approximately 25 nanometers).

The S/D contact 216 and the S/D contact 218 may be formed using any suitable processes known in the art. For example, one or more layers of metal and/or metal alloys may be deposited or otherwise provided to form the S/D contact 216 and the S/D contact 218. Any suitable ones of the embodiments of the S/D contact 216 and the S/D contact 218 described above may be used for any of the S/D contacts 216 and S/D contacts 218 described herein.

FIG. 7 depicts a transistor 220 including a transistor gate stack 204 and having a single “top” gate provided by the gate insulator 206 and the gate electrode material 208. In the embodiment of FIG. 7, the transistor gate stack 204 is shown as disposed above a support 222. The transistor 220 may include an S/D contact 216 and an S/D contact 218 disposed on the support 222. As discussed above, in some embodiments, the support 222 of FIG. 7 may include a semiconductor material and ILD disposed between the semiconductor material and the S/D contact 216, the channel material 202, and the S/D contact 218, to electrically isolate the semiconductor material of the support 222 from the S/D contact 216, the channel material 202, and the S/D contact 218. In some embodiments, any one or more of the gate insulator 206 and the gate electrode material 208 may conform around the S/D contact 216 and/or the S/D contact 218. An insulating material 226 may be disposed between the S/D contacts 216/218 and the transistor gate stack 204; the insulating material 226 may include any suitable insulating material, such as any of the ILDs discussed herein. Insulating material 226 on a channel material 202 may include a passivation material (e.g., hafnium oxide, zirconium oxide, aluminum oxide, silicon oxide, silicon nitride, silicon carbide, silicon oxycarbide, silicon oxynitride, titanium oxide, copper oxide, tin oxide, or copper tin oxide) in contact with the channel material 202. In some embodiments, the channel material 202 may include a semiconductor material with an insulating material dopant and/or an opposite conductivity type dopant proximate to the passivation material, and another material (e.g., a non-doped semiconductor material) distal to the passivation material (e.g., so that the semiconductor material with an insulating material dopant and/or an opposite conductivity type dopant is between the non-doped semiconductor material and the insulating material 226).

FIG. 8 depicts a transistor 220 including a transistor gate stack 204 and having a single “bottom” gate provided by the gate insulator 206 and the gate electrode material 208. In the embodiment of FIG. 8, the transistor gate stack 204 is shown as disposed on a support 222 in an orientation “upside down” to the one illustrated in FIG. 6; that is, the gate insulator 206 and the gate electrode material 208 may be disposed between the support 222 and the channel material 202. The transistor 220 may include an S/D contact 216 and an S/D contact 218 disposed on the channel material 202 such that the S/D contact 216 and the S/D contact 218 are not coplanar with the channel material 202. An insulating material 226 may be disposed between the S/D contacts 216 and 218, above the channel material 202.

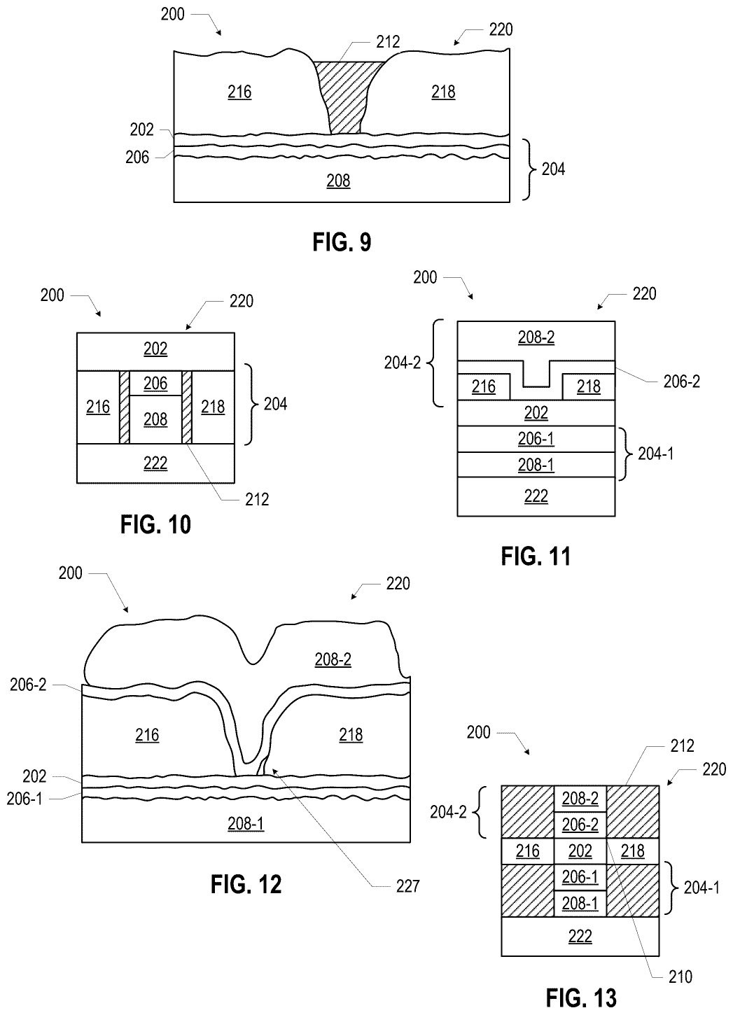

FIG. 9 depicts a transistor 220 having the structure of the transistor 220 of FIG. 8. In particular, the transistor 220 of FIG. 9 includes a transistor gate stack 204 and has a single “bottom” gate provided by the gate insulator 206 and the gate electrode material 208. The transistor 220 of FIG. 9 may also include a support 222 (not shown) arranged so that the gate insulator 206 and the gate electrode material 208 are disposed between the support 222 and the channel material 202. The transistor 220 may include an S/D contact 216 and an S/D contact 218 disposed on the channel material 202 such that the S/D contact 216 and the S/D contact 218 are not coplanar with the channel material 202. Any suitable materials may be used to form the transistor 220 of FIG. 9, as discussed above. For example, the gate electrode material 208 may include titanium nitride, the gate insulator 206 may include a FE/AFE material or a charge-trapping arrangement or a non-FE/AFE dielectric material, and the S/D contact 216 and the S/D contact 218 may include aluminum. The gate length of the transistor 220 of FIG. 9 may be approximately 25 nanometers.

FIG. 10 depicts a transistor 220 including a transistor gate stack 204 and having a single “bottom” gate provided by the gate insulator 206 and the gate electrode material 208. In the embodiment of FIG. 10, the transistor gate stack 204 is shown as disposed on a support 222 in an orientation “upside down” to the one illustrated in FIG. 6; that is, the gate insulator 206 and the gate electrode material 208 may be disposed between the support 222 and the channel material 202. The transistor 220 may include an S/D contact 216 and an S/D contact 218 disposed on the channel material 202 such that at least some of the S/D contact 216 and at least some of the S/D contact 218 are coplanar with at least some of the channel material 202. In some embodiments, the S/D contact 216 and the S/D contact 218 may each be disposed between some of the channel material 202 and the support 222, as illustrated in FIG. 10, while in other embodiments, the channel material 202 may not extend “above” the S/D contact 216 or the S/D contact 218. In some embodiments, the channel material 202 may conform around the S/D contact 216 and/or the S/D contact 218.

FIG. 11 depicts a double-gate transistor 220 including two transistor gate stacks 204-1 and 204-2 and having “bottom” and “top” gates. FIG. 11 illustrates that the transistor gate stack 204-1 is provided by the gate insulator 206-1 and the gate electrode material 208-1, while the transistor gate stack 204-2 is provided the gate insulator 206-2 and the gate electrode material 208-2. Each gate insulator 206 may be disposed between the corresponding gate electrode material 208 and the channel material 202. The transistor 220 may include an S/D contact 216 and an S/D contact 218 disposed proximate to the channel material 202. In the embodiment illustrated in FIG. 11, the S/D contact 216 and the S/D contact 218 are disposed on the channel material 202, and the gate insulator 206-2 is disposed conformably around the S/D contact 216, the channel material 202, and the S/D contact 218. The gate electrode material 208-2 is disposed on the gate insulator 206-2. In the embodiment of FIG. 11, at least some of the S/D contact 216 and at least some of the S/D contact 218 are coplanar with at least some of the gate insulator 206-2.

FIG. 12 depicts a double-gate transistor 220 having the structure of the transistor 220 of FIG. 11. In particular, the transistor 220 of FIG. 12 includes two transistor gate stacks 204-1 and 204-2 and having “bottom” and “top” gates as described with reference to FIG. 11. The transistor 220 of FIG. 12 may also include a support 222 (not shown) arranged so that the gate electrode material 208-1 is disposed between the support 222 and the gate insulator 206-1. The transistor 220 may include an S/D contact 216 and an S/D contact 218 disposed on the channel material 202 such that the S/D contact 216 and the S/D contact 218 are not coplanar with the channel material 202. In the embodiment depicted in FIG. 12, the S/D contact 216 and the S/D contact 218 may be deposited on the channel material 202. During manufacture, a void 227 may be formed between the gate insulator 206-2 and the channel material 202; while such voids 227 may reduce the performance of the transistor 220, the transistor 220 may still function adequately as long as adequate coupling between the gate insulator 206-2 and the channel material 202 is achieved. Any suitable materials may be used to form the transistor 220 of FIG. 12, as discussed above. For example, the gate electrode material 208-1 may be titanium nitride, any of the gate insulators 206-1 and 206-2 may include a FE/AFE material or a charge-trapping arrangement or a non-FE/AFE dielectric material, the S/D contact 216 and the S/D contact 218 may include aluminum, and the gate electrode material 208-2 may include palladium. In some embodiments, the gate length of the transistor 220 of FIG. 12 may be approximately 25 nanometers.

FIG. 13 depicts a double-gate transistor 220 including two transistor gate stacks 204-1 and 204-2 and having “bottom” and “top” gates. FIG. 13 illustrates that the transistor gate stack 204-2 is provided by the gate insulator 206-2 and the gate electrode material 208-2, while the transistor gate stack 204-1 is provided by the gate insulator 206-1 and the gate electrode material 208-1. Each gate insulator 206 may be disposed between the corresponding gate electrode material 208 and the channel material 202. The transistor 220 may include an S/D contact 216 and an S/D contact 218 disposed proximate to the channel material 202. In the embodiment illustrated in FIG. 13, the S/D contact 216 and the S/D contact 218 are coplanar with the channel material 202 and disposed between the gate insulators 206-1 and 206-2. The relative arrangement of the S/D contact 216, the S/D contact 218, and the channel material 202 may take the form of any of the embodiments discussed above with reference to FIG. 6.

FIGS. 14A and 14B are perspective and cross-sectional side views, respectively, of an example tri-gate transistor 220 including a fin 232 that may include a channel material 202 and a transistor gate stack 204 over a portion of the fin 232, in accordance with various embodiments. In the tri-gate transistor 220 illustrated in FIGS. 14A and 14B, a fin 232 formed of a semiconductor material may extend from a base 240 of the semiconductor material. The base 240 may be any structure from which the fin 232 may extend; descriptions provided for the support 222 are applicable to the base 240. An oxide material 230 may be disposed on either side of the fin 232. In some embodiments, the oxide material 230 may include a shallow trench isolation (STI) material. The transistor 220 of FIGS. 14A and 14B may include a channel material 202 in the fin 232, and may further include a transistor gate stack 204 including the gate insulator 206 and the gate electrode material 208. FIG. 14A is a perspective drawing, an example coordinate system 205 (x-y-z coordinate system) is shown there to assist explanations. The coordinate system 205 is also shown in FIG. 15A, and other drawings illustrating axes (e.g., FIG. 14B, and FIG. 15B, illustrating y-z planes) refer to the coordinate system 205.

Some or all layers of the transistor gate stack 204 may wrap around the fin 232, with the channel material 202 corresponding to the portion of the fin 232 wrapped by the transistor gate stack 204. For example, as shown in FIG. 14B, the gate insulator 206 and the gate electrode material 208 may wrap around the fin 232. The fin 232 may include an S/D contact 216 and an S/D contact 218 on either side of the transistor gate stack 204, as shown. The composition of the channel material 202, the S/D contact 216, and the S/D contact 218 may take the form of any of the embodiments disclosed herein, or known in the art. Although the fin 232 illustrated in FIGS. 14A and 14B is shown as having a rectangular cross-section, the fin 232 may instead have a cross-section that is rounded or sloped at the “top” of the fin 232, and the transistor gate stack 204 may conform to this rounded or sloped fin 232. In use, the tri-gate transistor 220 may form conducting channels on three “sides” of the fin 232, potentially improving performance relative to single-gate transistors (which may form conducting channels on one “side” of the channel material 202) and double-gate transistors (which may form conducting channels on two “sides” of the channel material 202). Because the tri-gate transistor 220 is based on a fin 232, it is also commonly referred to as a FinFET.

FIGS. 15A and 15B are perspective and cross-sectional side views, respectively, of an example all-around gate transistor 220 including a wire 236 that may include a channel material 202 and a transistor gate stack 204 over a portion of the wire 236, in accordance with various embodiments. In the all-around gate transistor 220 illustrated in FIGS. 15A and 15B, a wire 236 formed of a semiconductor material may extend above a support 234 and a layer of oxide material 230. The support 234 may be any structure from over which the wire 236 may extend; descriptions provided for the support 222 are applicable to the support 234. The wire 236 may take the form of a nanowire or nanoribbon, for example. The transistor 220 of FIGS. 15A and 15B may further include a channel material 202 in the wire 236, and a transistor gate stack 204 including the gate insulator 206 and the gate electrode material 208. Some or all layers of the transistor gate stack 204 may wrap entirely or almost entirely around the wire 236, with the channel material 202 corresponding to the portion of the wire 236 wrapped by the transistor gate stack 204. In some embodiments, some or all layers of the transistor gate stack 204 may fully encircle the wire 236. For example, as shown in FIG. 15B, the gate insulator 206 and the gate electrode material 208 may wrap entirely or almost entirely around the wire 236. The wire 236 may include an S/D contact 216 and an S/D contact 218 on either side of the transistor gate stack 204, as shown. The composition of the channel material 202, the S/D contact 216, and the S/D contact 218 may take the form of any of the embodiments disclosed herein, or known in the art. Although the wire 236 illustrated in FIGS. 15A and 15B is shown as having a rectangular cross-section, the wire 236 may instead have a cross-section that is rounded or otherwise irregularly shaped, and the transistor gate stack 204 may conform to the shape of the wire 236. In use, the tri-gate transistor 220 may form conducting channels on more than three “sides” of the wire 236, potentially improving performance relative to tri-gate transistors. Although FIGS. 15A and 15B depict an embodiment in which the longitudinal axis of the wire 236 runs substantially parallel to a plane of the oxide material 230 (and a plane of the support 234), this need not be the case; in other embodiments, for example, the wire 236 may be oriented “vertically” so as to be perpendicular to a plane of the oxide material 230 (or plane of the support 234). Because the all-around gate transistor 220 is based on a wire 236, it is also commonly referred to as a nanowire/nanoribbon transistor.

FIG. 16 is an electric circuit diagram of an example 6-transistor (6T) SRAM cell 300, according to some embodiments. As shown in FIG. 16, the SRAM cell 300 includes transistors M1-M4 for storing a bit value or a memory state (e.g., logic “1” or “0”) of the cell, and two access transistors, M5 and M6, for controlling access to the cell (e.g., access to write information to the cell or access to read information from the SRAM cell 300). Each of the transistors M1-M6 may include a gate 312, a first S/D region 314, and a second S/D region 316 (e.g., the first S/D region 314 may be a source region and the second S/D region 316 may be a drain region, or vice versa), where the gate 312, the first S/D region 314, and the second S/D region 316 of different transistors are denoted in FIG. 16 with different reference numerals after the dash, the reference numerals being the same as in one of the transistors M1-M6. For example, the transistor M2 includes a gate 312-2, a first S/D region 314-2, and a second S/D region 316-2, while the transistor M5 includes a gate 312-5, a first S/D region 314-5, and a second S/D region 316-5. Each of the transistors M1-M6 may be a transistor of any transistor architecture (e.g., planar or non-planar, FinFET, nanoribbon/nanowire, etc.). For example, each of the transistors M1-M6 of the SRAM cell 300 may be any of the transistors 220 described with reference to FIGS. 5-15. The gate 312 of any of the transistors of the SRAM cell 300 may be implemented as the transistor gate stack 204 of FIGS. 5-15, the first S/D region 314 and the second S/D region 316 of any of the transistors of the SRAM cell 300 may be implemented as the S/D regions of any of the transistors 220 of FIGS. 6-15.

In the SRAM cell 300, a bit may be stored on four transistors (M1, M2, M3, M4) that form two cross-coupled inverters 320, each having an input 322 and an output 324. The first inverter 320-1 may be formed by an NMOS transistor M1 and a PMOS transistor M2, while the second inverter 320-2 may be formed by an NMOS transistor M3 and a PMOS transistor M4. As shown in FIG. 16, the gate 312-1 of the transistor M1 may be coupled to the gate 312-2 of the transistor M2, and both of these gates may be coupled to the input 322-1 of the first inverter 320-1. On the other hand, the first S/D region 314-1 of the transistor M1 may be coupled to the first S/D region 314-2 of the transistor M2, and both of these first S/D regions 314-1 and 314-2 may be coupled to the output 324-1 of the first inverter 320-1. Similarly, for the second inverter 320-2, the gate 312-3 of the transistor M3 may be coupled to the gate 312-4 of the transistor M4, and both of these gates may be coupled to the input 322-2 of the second inverter 320-2, while the first S/D region 314-3 of the transistor M3 may be coupled to the first S/D region 314-4 of the transistor M4, and both of these first S/D regions 314-3 and 314-4 may be coupled to the output 324-2 of the second inverter 320-2. As also shown in FIG. 16, when the transistors M1 and M3 are NMOS transistors and when the transistors M2 and M4 are PMOS transistors as illustrated in FIG. 16, the second S/D regions 316-1 and 316-3 of the transistors M1 and M3 may be coupled to a ground voltage 332, while the second S/D regions 316-2 and 316-4 of the transistors M2 and M4 may be coupled to a supply voltage 334, e.g., VDD. In the embodiments of the SRAM cell 300 where the NMOS transistors shown in FIG. 16 are replaced with PMOS transistors and vice versa, the designation of the ground voltage 332 and the supply voltage 334 would be reversed as well.

The four transistors M1-M4 in the illustrated configuration form a stable storage cell for storing a bit value of 0 or 1. As further shown in FIG. 16, two additional access transistors, M5 and M6, may serve to control the access to the storage cell of the transistors M1-M4 during read and write operations. As shown in FIG. 16, the first S/D region 314-5 of the access transistor M5 may be coupled to the output 324-1 of the first inverter 320-1. Phrased differently, the first S/D region 314-5 of the access transistor M5 may be coupled to each of the first S/D region 314-1 of the transistor M1 and the first S/D region 314-2 of the transistor M2. The second S/D region 316-5 of the access transistor M5 may be coupled to the first BL 340-1. Thus, each of the first S/D region 314-1 of the transistor M1 and the first S/D region 314-2 of the transistor M2 may be coupled to the first BL 340-1 (e.g., via the access transistor M5). The gate 312-5 of the access transistor M5 may be coupled to a WL 350.

As further shown in FIG. 16, the first S/D region 314-6 of the access transistor M6 may be coupled to the output 324-2 of the second inverter 320-2. Phrased differently, the first S/D region 314-6 of the access transistor M6 may be coupled to each of the first S/D region 314-3 of the transistor M3 and the first S/D region 314-4 of the transistor M4. The second S/D region 316-6 of the access transistor M6 may be coupled to a second BL 340-2. Thus, each of the first S/D region 314-3 of the transistor M3 and the first S/D region 314-4 of the transistor M4 may be coupled to the second BL 340-2 (e.g., via the access transistor M6). The gate 312-6 of the access transistor M6 may be coupled to the WL 350. Thus, the gates 312-5 and 312-6 of both of the access transistors M5 and M6 may be coupled to a single, shared, WL, the WL 350.

As also shown in FIG. 16, the input 322-1 of the first inverter 320-1 may be coupled to the first S/D region 314-6 of the access transistor M6, while the input 322-2 of the second inverter 320-2 may be coupled to the first S/D region 314-5 of the access transistor M5. In other words, each of the gate 312-1 of the transistor M1 and the gate 312-2 of the transistor M2 may be coupled to the first S/D region 314-6 of the access transistor M6, while each of the gate 312-3 of the transistor M3 and the gate 312-4 of the transistor M4 may be coupled to the first S/D region 314-5 of the access transistor M5. Phrased differently, each of the gate 312-1 of the transistor M1 and the gate 312-2 of the transistor M2 may be coupled to the second BL 340-2 (e.g., via the access transistor M6), while each of the gate 312-3 of the transistor M3 and the gate 312-4 of the transistor M4 may be coupled to the first BL 340-1 (e.g., via the access transistor M5).

The WL 350 and the first and second BLs 340 may be used together to read and program (i.e., write to) the SRAM cell 300. In particular, access to the cell may be enabled by the WL 350 which controls the two access transistors M5 and M6 which, in turn, control whether the SRAM cell 300 should be connected to the BLs 340-1 and 340-2. During operation of the SRAM cell 300, a signal on the first BL 340-1 may be complementary to a signal on the second BL 340-2. The two BLs 340 may be used to transfer data for both read and write operations. In other embodiments of the SRAM cell 300, only a single BL 340 may be used, instead of two BLs 340-1 and 340-2, although having one signal BL and one inverse, such as the two BLs 340, may help improve noise margins.

During read accesses, the BLs 340 are actively driven high and low by the inverters 320 in the SRAM cell 300. This may improve SRAM bandwidth compared to DRAM. The symmetric structure of the SRAMs cell 300 also allows for differential signaling, which may provide an improvement in detecting small voltage swings. Another difference with DRAM that may contribute to making SRAM faster than DRAM is that commercial chips accept all address bits at a time. By comparison, commodity DRAMs may have the address multiplexed in two halves, i.e. higher bits followed by lower bits, over the same package pins in order to keep their size and cost down.

Each of the WL 350 and the BLs 340, as well as intermediate elements coupling these lines to various terminals described herein, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 17 is an electric circuit diagram of an example DRAM cell 400, according to some embodiments. As shown in FIG. 17, the DRAM cell 400 includes one transistor M and one capacitor C. The capacitor C is for storing a memory state (e.g., logical “1” or “0”) of the DRAM cell 400, while the transistor M is an access transistor controlling access to the DRAM cell 400 (e.g., access to write information to the DRAM cell 400 or access to read information from the DRAM cell 400). Such a memory cell may be referred to as a “1T-1C memory cell,” highlighting the fact that it uses one access transistor (i.e., “1T” in the term “1T-1C memory cell”) and one capacitor (i.e., “1C” in the term “1T-1C memory cell”). Since such a memory cell can be fabricated with as little as a single access transistor, it can provide higher density and lower standby power versus some other types of memory in the same process technology. In other embodiments, the DRAM cell 400 may include a plurality of capacitors connected in parallel to the capacitor C, to increase the storage capacity of the DRAM cell 400. The transistor M of the DRAM cell 400 includes a gate 412, a first S/D region 414, and a second S/D region 414, which may be as described above. The capacitor C includes a first capacitor electrode 444 and a second capacitor electrode 446. As shown in FIG. 17, in the DRAM cell 400, the gate 412 may be coupled to a WL 450, the first S/D region 414 may be coupled to the first capacitor electrode 444, the second S/D region 416 may be coupled to a BL 440, and the second capacitor electrode 446 may be coupled to a plateline (PL) 460. As is known in the art, the BL 440, the WL 450, and the PL 460 may be used together to read and program the capacitor C.

The transistor M of the DRAM cell 400 may be a transistor of any transistor architecture (e.g., planar or non-planar, FinFET, nanoribbon/nanowire, etc.). For example, the transistor M may be any of the transistors 220 described with reference to FIGS. 5-15. The gate 412 of the transistor M may be implemented as the transistor gate stack 204 of FIGS. 5-15, the first S/D region 414 and the second S/D region 416 of the transistor M may be implemented as the S/D regions of any of the transistors 220 of FIGS. 6-15. The capacitor C of the DRAM cell 400 may be a capacitor of any transistor architecture (e.g., a planar capacitor, a three-dimensional capacitor, etc.). As is known in the art, the capacitor C includes a capacitor insulator between the first capacitor electrode 444 and the second capacitor electrode 446. The capacitor insulator may include any of the materials described with reference to the gate insulator 206. Each of the BL 440, the WL 450, the PL 460, the first capacitor electrode 444, and the second capacitor electrode 446, as well as intermediate elements coupling these elements, may be formed of any suitable electrically conductive material, which may include an alloy or a stack of multiple electrically conductive materials. In some embodiments, such electrically conductive materials may include one or more metals or metal alloys, with metals such as ruthenium, palladium, platinum, cobalt, nickel, hafnium, zirconium, titanium, tantalum, and aluminum. In some embodiments, such electrically conductive materials may include one or more electrically conductive alloys oxides or carbides of one or more metals.

FIG. 18 is an electric circuit diagram of an example SRAM tag 500, according to some embodiments. As shown in FIG. 18, the SRAM tag 500 includes an SRAM cell such as the SRAM cell 300 described above, and further includes a first logic gate 510 and a second logic gate 520. One of the first logic gate 510 and the second logic gate 520 may be a NAND gate and the other one may be an AND gate. As such, each of the first logic gate 510 and the second logic gate 520 may include two inputs and one output. For the first logic gate 510, the first BL 340-1 of the SRAM cell 300 may be coupled (e.g., directly electrical connected) to a first input 512 of the first logic gate 510, an output of the compute die 103-2 may be coupled (e.g., directly electrical connected) to a second input 514 of the first logic gate 510, and an output 516 of the first logic gate 510 may be coupled to an input of the compute die 103-2. Similarly, for the second logic gate 520, the second BL 340-2 of the SRAM cell 300 may be coupled (e.g., directly electrical connected) to a first input 522 of the second logic gate 520, an output of the compute die 103-2 may be coupled (e.g., directly electrical connected) to a second input 524 of the second logic gate 520, and an output 526 of the second logic gate 520 may be coupled to an input of the compute die 103-2. The first logic gate 510 may use the two inputs received at the first input 512 and the second input 514 to generate an output at the output 516 to provide to the compute die 103-2. The second logic gate 520 may use the two inputs received at the first input 522 and the second input 524 to generate an output at the output 526 to provide to the compute die 103-2. The inputs provided by the compute die 103-2 to the first input 512 and the first input 522 may be queries, or requests to determine, whether a particular piece of data is available in the cache memory of the cache memory die 103-3. The outputs provided at the output 516 and the output 526 may be outputs indicative of, or outputs that allow determining, whether the requested piece of data is available in the cache memory of the cache memory die 103-3. For example, in some embodiments, the outputs provided at the output 516 and the output 526 may be coupled to various control lines of the SRAM cells 300 of an SRAM memory array of the cache memory die 103-3. For example, in some embodiments, the outputs provided at the output 516 and the output 526 may be coupled to WLs 350 of the SRAM cells 300 of an SRAM memory array of the cache memory die 103-3 via a row decoder of the SRAM memory array and may be coupled to the BLs 340 of the SRAM cells 300 of an SRAM memory array of the cache memory die 103-3 via a column decoder of the SRAM memory array.

A tags die 103-1 may include a plurality of tags such as the SRAM tag 500, configured to receive requests from the compute die 103-2 to determine whether a requested piece of data is available in the cache memory of the cache memory die 103-3, and to output results. Thus, the tags die 103-1 includes a plurality of SRAM cells 300 as part of the SRAM tags 500. The SRAM cells 300 of the SRAM tags 500 of the tags die 103-1 are separate from the SRAM cells 300 of the memory cells of the cache memory die 103-3, but are coupled (e.g., directly electrical connected) to the SRAM cells 300 of the memory cells of the cache memory die 103-3 so that they can provide information as to whether a requested piece of data is available in the cache memory of the cache memory die 103-3.

Disintegration of the SRAM tags 500 from the memory cells of the cache memory die 103-3 may provide significant advantages. For example, in some embodiments, the memory cells of the cache memory die 103-3 may be implemented using different types of memory than the SRAM cells 300 of the SRAM tags 500. In some embodiments, the memory cells of the cache memory die 103-3 may be implemented as the DRAM cells 400. In another example, in some embodiments, the memory cells of the cache memory die 103-3 may be implemented using transistors of a first architecture, different from a second architecture used for transistors of the SRAM tags 500. In some embodiments, transistors of the SRAM tags 500 may be implemented using simpler and/or less expensive architecture than transistors of the memory cells of the cache memory die 103-3. For example, transistors of the SRAM tags 500 may be implemented as planar transistors (e.g., as any of the transistors 220 of FIGS. 6-13, or as any combination of such transistors), while transistors of the memory cells of the cache memory die 103-3 (which may include SRAM cells 300, or DRAM cells 400, or memory cells of any other memory technology) may be implemented as non-planar transistors (e.g., as any of the transistors 220 of FIGS. 14A-14B or FIGS. 15A-15B, or as any combination of such transistors). In another example, transistors of the SRAM tags 500 may be implemented as FinFETs (e.g., as the transistors 220 of FIGS. 14A-14B), while transistors of the memory cells of the cache memory die 103-3 (which may include SRAM cells 300, or DRAM cells 400, or memory cells of any other memory technology) may be implemented as nanowire/nanoribbon transistors (e.g., as the transistors 220 of FIGS. 15A-15B). In yet another example, transistors of the SRAM tags 500 may be implemented as TFTs (e.g., as any of the transistors 220 of FIGS. 6-13, or as any combination of such transistors), while transistors of the memory cells of the cache memory die 103-3 (which may include SRAM cells 300, or DRAM cells 400, or memory cells of any other memory technology) may be implemented as transistors other than TFTs (e.g., as any of the transistors 220 of FIGS. 6-13, FIGS. 14A-14B, or FIGS. 15A-15B, or as any combination of such transistors). In still another example, transistors of the memory cells of the cache memory die 103-3 (which may include SRAM cells 300, or DRAM cells 400, or memory cells of any other memory technology) may be implemented as TFTs (e.g., as any of the transistors 220 of FIGS. 6-13, or as any combination of such transistors), while transistors of the SRAM tags 500 may be implemented as transistors other than TFTs (e.g., as any of the transistors 220 of FIGS. 6-13, FIGS. 14A-14B, or FIGS. 15A-15B, or as any combination of such transistors).

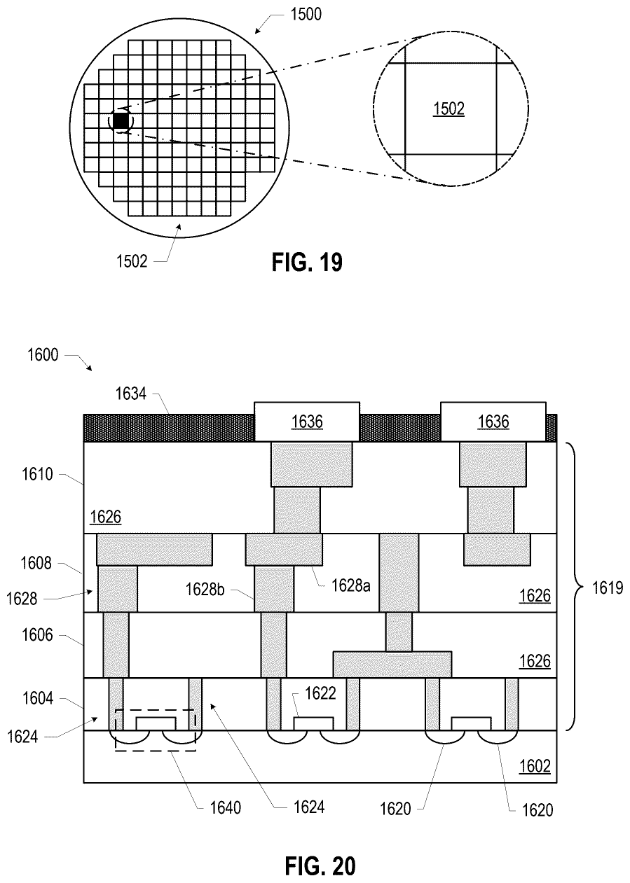

The dies 102 and microelectronic assemblies 100 disclosed herein may be included in any suitable electronic component. FIGS. 19-22 illustrate various examples of apparatuses that may include, or be included in, as suitable, any of the dies 102 and microelectronic assemblies 100 with tags disintegrated from cache memory disclosed herein.

FIG. 19 is a top view of a wafer 1500 and dies 1502 that may be included in any of the dies 102 disclosed herein. For example, a die 1502 may serve as a die 102, or may be included in a die 102. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more transistors (e.g., any of the transistors of the microelectronic assemblies 100 with tags disintegrated from cache memory disclosed herein, e.g., any of the transistors 220, described above, or any of the transistors 1640 of FIG. 20, discussed below) and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. In some embodiments, the die 1502 may be any of the tags die 103-1, the compute die 103-2, or the cache memory die 103-3 disclosed herein. Multiple ones of these devices may be combined on a single die 1502. For example, a memory array formed by multiple memory devices may be formed on a same die 1502 as a processing device (e.g., the processing device 1802 of FIG. 22) or other logic that is configured to store information in the memory devices or execute instructions stored in the memory array.

FIG. 20 is a side, cross-sectional view of an IC device 1600 that may be included in any of the dies 102 disclosed herein. For example, an IC device 1600 (e.g., as part of a die 1502, as discussed above with reference to FIG. 19) may serve as a die 102, or may be included in a die 102. One or more of the IC devices 1600 may be included in one or more dies 1502 (FIG. 19). The IC device 1600 may be formed on a substrate 1602 (e.g., the wafer 1500 of FIG. 19) and may be included in a die (e.g., the die 1502 of FIG. 19). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 1502 of FIG. 19) or a wafer (e.g., the wafer 1500 of FIG. 19).

The IC device 1600 may include one or more device layers 1604 disposed on the substrate 1602. The device layers 1604 may also be referred to as FEOL layers. The device layer 1604 may include features of one or more transistors 1640 (e.g., metal oxide semiconductor field-effect transistors (MOSFETs)) formed on the substrate 1602. The device layer 1604 may include, for example, one or more S/D regions 1620, a gate 1622 to control current flow in the transistors 1640 between the S/D regions 1620, and one or more S/D contacts 1624 (e.g., the S/D contacts 216, 218, described above) to route electrical signals to/from the S/D regions 1620. The transistors 1640 may include additional features not depicted for the sake of clarity, such as device isolation regions, gate contacts, and the like. The transistors 1640 are not limited to the type and configuration depicted in FIG. 20 and may include a wide variety of other types and configurations such as, for example, planar transistors, non-planar transistors, or a combination of both.

Each transistor 1640 may include a gate 1622 that includes a gate electrode material and, optionally, a gate insulator. Descriptions provided with respect to the gate electrode material 208 and the gate insulator 206 are applicable to the gate electrode material and the gate insulator of the gate 1622. In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack of the gate 1622 to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group III-V material or alloy. In further embodiments, one or more layers of metal and/or metal alloys may be used to form the S/D regions 1620.

Electrical signals, such as power and/or input/output (I/O) signals, may be routed to and/or from the devices (e.g., the transistors 1640) of the device layer 1604 through one or more interconnect layers disposed on the device layer 1604 (illustrated in FIG. 20 as interconnect layers 1606, 1608, and 1610). For example, electrically conductive features of the device layer 1604 (e.g., the gate 1622 and the S/D contacts 1624) may be electrically coupled (e.g., directly electrical connected) with the interconnect structures 1628 of the interconnect layers 1606, 1608, and 1610. The one or more interconnect layers 1606, 1608, and 1610 may form a metallization stack (also referred to as an “ILD stack”) 1619 of the IC device 1600.

The interconnect structures 1628 may be arranged within the interconnect layers 1606, 1608, and 1610 to route electrical signals according to a wide variety of designs (in particular, the arrangement is not limited to the particular configuration of interconnect structures 1628 depicted in FIG. 20). Although a particular number of interconnect layers 1606, 1608, and 1610 is depicted in FIG. 20, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 20. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606, 1608, and 1610 together.

The interconnect layers 1606, 1608, and 1610 may include a dielectric material 1626 disposed between the interconnect structures 1628, as shown in FIG. 20. In some embodiments, the dielectric material 1626 disposed between the interconnect structures 1628 in different ones of the interconnect layers 1606, 1608, and 1610 may have different compositions; in other embodiments, the composition of the dielectric material 1626 between different interconnect layers 1606, 1608, and 1610 may be the same.

A first interconnect layer 1606 may be formed above the device layer 1604. In some embodiments, the first interconnect layer 1606 may include lines 1628a and/or vias 1628b, as shown. The lines 1628a of the first interconnect layer 1606 may be coupled (e.g., directly electrical connected) with contacts (e.g., the S/D contacts 1624) of the device layer 1604.

A second interconnect layer 1608 may be formed above the first interconnect layer 1606. In some embodiments, the second interconnect layer 1608 may include vias 1628b to couple the lines 1628a of the second interconnect layer 1608 with the lines 1628a of the first interconnect layer 1606. Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual-damascene process) in some embodiments.

A third interconnect layer 1610 (and additional interconnect layers, as desired) may be formed in succession on the second interconnect layer 1608 according to similar techniques and configurations described in connection with the second interconnect layer 1608 or the first interconnect layer 1606. In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606, 1608, and 1610. In FIG. 20, the conductive contacts 1636 are illustrated as taking the form of bond pads. The conductive contacts 1636 may be electrically coupled (e.g., directly electrical connected) with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606, 1608, and 1610; for example, the conductive contacts 1636 may include other analogous features (e.g., posts) that route the electrical signals to external components.

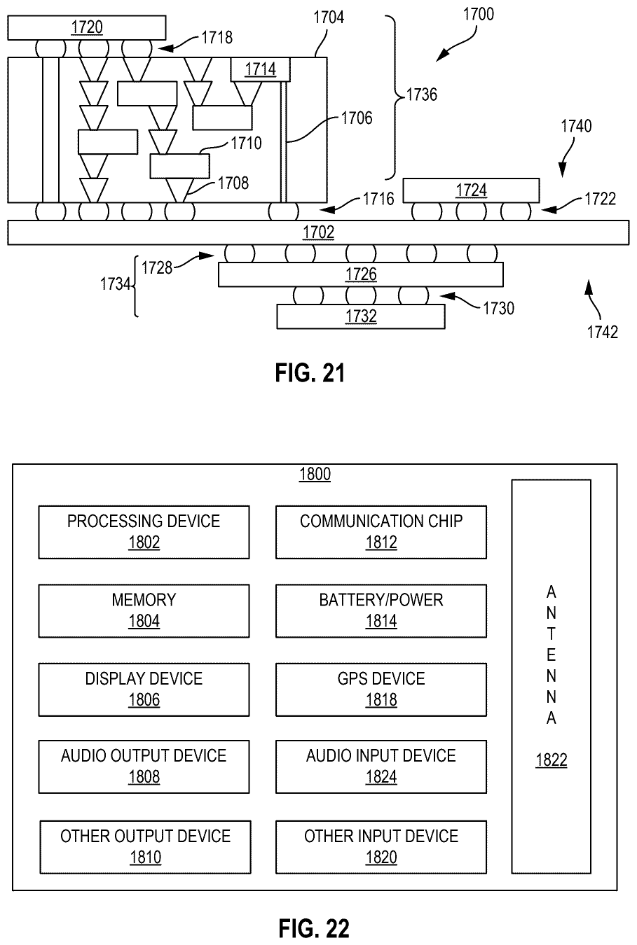

FIG. 21 is a side, cross-sectional view of an IC device assembly 1700 that may include any of the dies 102 and/or microelectronic assemblies 100 disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may include any of the embodiments of the microelectronic assemblies 100 disclosed herein (e.g., may include stacks of multiple dies 102 with tags disintegrated from cache memory as described herein).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 21 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 21), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 21, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 19), an IC device (e.g., the IC device 1600 of FIG. 20), or any other suitable component. The IC package 1720 may include stacks of multiple dies 102 with tags disintegrated from cache memory disclosed herein, e.g., any of the microelectronic assemblies 100 disclosed herein. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 21, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to TSVs 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 21 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 22 is a block diagram of an example electrical device 1800 that may include any of the dies 102 (e.g., stacks of multiple dies 102 with tags disintegrated from cache memory disclosed herein) and/or any of the microelectronic assemblies 100 disclosed herein. For example, any suitable ones of the components of the electrical device 1800 may include one or more of the IC device assemblies 1700, IC devices 1600, or dies 1502 disclosed herein. A number of components are illustrated in FIG. 22 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 22, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), CPUs, graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides a microelectronic assembly that includes a first die including cache memory with an array of DRAM cells, and further includes a second die including SRAM tags for determining whether a requested piece of data is available in the cache memory, the SRAM tags coupled to the array of the DRAM cells, wherein the first die and the second die are stacked above one another in a stack of dies.

Example 2 provides the microelectronic assembly according to example 1, in which the DRAM cells of the first die include transistors of a first transistor architecture, and the SRAM tags of the second die include transistors of a second transistor architecture.

Example 3 provides the microelectronic assembly according to example 2, in which the transistors of the first transistor architecture are non-planar transistors, and the transistors of the second transistor architecture are planar transistors.

Example 4 provides the microelectronic assembly according to example 2, in which the transistors of the first transistor architecture are nanoribbon transistors, and the transistors of the second transistor architecture are FinFETs.

Example 5 provides the microelectronic assembly according to any one of examples 1-4, further including a third die including logic circuitry (e.g., a compute die) coupled to the SRAM tags, the logic circuitry configured to control operation of the tags (e.g., for initiating that tags are to be used to determine whether a requested piece of data is available in the cache memory; in some embodiments, the logic circuitry may be configured to fetch the requested piece of data from the cache memory once the tags output the result that the requested piece of data is available in the cache memory; in other embodiments, the tags may be configured to fetch the requested piece of data from the cache memory and provide it to the logic circuitry once the tags output the result that the requested piece of data is available in the cache memory), in which the third die is included in the stack of dies.

Example 6 provides the microelectronic assembly according to example 5, in which the third die is adjacent to the second die within the stack of dies (two dies may be described as adjacent to one another within a stack of dies if they are connected to one another by DBIs or solder-based DTDs).

Example 7 provides the microelectronic assembly according to examples 5 or 6, in which the third die is between the first die and the second die within the stack of dies (i.e., the first die and the third die are adjacent to one another in the stack of dies, and the third die and the second die are adjacent to one another in the stack of dies).

Example 8 provides the microelectronic assembly according to examples 5 or 6, in which the second die is between the first die and the third die within the stack of dies (i.e., the first die and the second die are adjacent to one another in the stack of dies, and the second die and the third die are adjacent to one another in the stack of dies).

Example 9 provides the microelectronic assembly according to any one of examples 1-8, in which adjacent dies of the stack of dies are electrically coupled to one another by direct bonding interconnects.

Example 10 provides the microelectronic assembly according to any one of examples 1-8, in which adjacent dies of the stack of dies are electrically coupled to one another by solder-based die-to-die interconnects.

Example 11 provides the microelectronic assembly according to any one of examples 1-10, in which the stack of dies is a first stack, and in which the microelectronic assembly further includes a second stack of dies, in which the dies of the second stack include main memory.

Example 12 provides the microelectronic assembly according to example 11, further including an interposer, in which the first stack of dies and the second stack of dies are coupled to the interposer.

Example 13 provides the microelectronic assembly according to any one of examples 1-12, in which the SRAM tags are absent from the first die.

Example 14 provides a microelectronic assembly, including a first die including cache memory, in which the cache memory includes an array of memory cells; and a second die including tags for determining whether a requested piece of data is available in the cache memory, in which the first die and the second die are stacked above one another in a stack of dies.

Example 15 provides the microelectronic assembly according to example 14, in which the memory cells of the first die include transistors of a first transistor architecture, and the tags of the second die include transistors of a second transistor architecture.

Example 16 provides the microelectronic assembly according to example 15, in which the transistors of the first transistor architecture are non-planar transistors, and the transistors of the second transistor architecture are planar transistors.

Example 17 provides the microelectronic assembly according to example 15, in which the transistors of the first transistor architecture are nanoribbon transistors, and the transistors of the second transistor architecture are FinFETs.

Example 18 provides the microelectronic assembly according to any one of examples 14-17, in which the memory cells of the first die are DRAM cells, and the tags of the second die are SRAM tags.

Example 19 provides a microelectronic assembly, including a microelectronic component; and a stack of dies coupled to the microelectronic component, in which the stack of dies includes a first die including cache memory and a second die including tags for determining whether a requested piece of data is available in the cache memory, and in which the cache memory includes transistors of a first transistor architecture, the tags include transistors of a second transistor architecture, different from the first architecture, and the microelectronic component is one of an interposer, a package substrate, a circuit board, or a further die.

Example 20 provides the microelectronic assembly according to example 19, in which the cache memory includes DRAM cells, and the tags include SRAM cells.

Example 21 provides a system, including a circuit board; and a microelectronic assembly, communicatively coupled to the circuit board, in which the microelectronic assembly is a microelectronic assembly according to any one of the preceding examples.

Example 22 provides the system according to example 21, in which the circuit board is a motherboard.

Example 23 provides the system according to examples 21 or 22, in which the system further includes a display communicatively coupled to the circuit board.

Example 24 provides the system according to any one of examples 21-23, in which the system is a handheld computing system.

Example 25 provides the system according to any one of examples 21-24, in which the system is a wearable computing system.

Example 26 provides the system according to any one of examples 21-23, in which the system is a server computing system.

Example 27 provides the system according to any one of examples 21-23, in which the system is a vehicular computing system.

Example 28 provides the system according to any one of examples 21-27, in which the system further includes a wireless communication device communicatively coupled to the circuit board.

Example 29 provides the system according to any one of examples 21-27, in which the system further includes a housing around the microelectronic assembly and the circuit board.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. A microelectronic assembly, comprising:
a first die comprising cache memory, wherein the cache memory includes an array of dynamic random-access memory (DRAM) cells; and
a second die comprising static random-access memory (SRAM) tags coupled to the array of the DRAM cells,
wherein the first die and the second die are stacked above one another in a stack of dies.

2. The microelectronic assembly according to claim 1, wherein the DRAM cells of the first die include transistors of a first transistor architecture, and the SRAM tags of the second die include transistors of a second transistor architecture.

3. The microelectronic assembly according to claim 2, wherein the transistors of the first transistor architecture are non-planar transistors, and the transistors of the second transistor architecture are planar transistors.

4. The microelectronic assembly according to claim 2, wherein the transistors of the first transistor architecture are nanoribbon transistors, and the transistors of the second transistor architecture are FinFETs.

5. The microelectronic assembly according to claim 1, further comprising:
a third die comprising logic circuitry coupled to the SRAM tags,
wherein the third die is in the stack of dies.

6. The microelectronic assembly according to claim 5, wherein the third die is adjacent to the second die within the stack of dies.

7. The microelectronic assembly according to claim 5, wherein the third die is between the first die and the second die within the stack of dies.

8. The microelectronic assembly according to claim 5, wherein the second die is between the first die and the third die within the stack of dies.

9. The microelectronic assembly according to claim 1, wherein adjacent dies of the stack of dies are coupled to one another by direct bonding interconnects.

10. The microelectronic assembly according to claim 1, wherein adjacent dies of the stack of dies are coupled to one another by solder-based die-to-die interconnects.

11. The microelectronic assembly according to claim 1, wherein the stack of dies is a first stack, and wherein the microelectronic assembly further includes:
a second stack of dies,
wherein the dies of the second stack include main memory.

12. The microelectronic assembly according to claim 11, further comprising an interposer, wherein the first stack of dies and the second stack of dies are coupled to the interposer.

13. The microelectronic assembly according to claim 11, wherein the SRAM tags are absent from the first die.

14. A microelectronic assembly, comprising:
a first die comprising cache memory, wherein the cache memory includes an array of memory cells; and
a second die comprising tags for determining whether a requested piece of data is available in the cache memory,
wherein the first die and the second die are stacked above one another in a stack of dies.

15. The microelectronic assembly according to claim 14, wherein the memory cells of the first die include transistors of a first transistor architecture, and the tags of the second die include transistors of a second transistor architecture.

16. The microelectronic assembly according to claim 15, wherein the transistors of the first transistor architecture are non-planar transistors, and the transistors of the second transistor architecture are planar transistors.

17. The microelectronic assembly according to claim 15, wherein the transistors of the first transistor architecture are nanoribbon transistors, and the transistors of the second transistor architecture are FinFETs.

18. The microelectronic assembly according to claim 14, wherein the memory cells of the first die are dynamic random-access memory (DRAM) cells, and the tags of the second die are static random-access memory (SRAM) tags.

19. A microelectronic assembly, comprising:
a microelectronic component; and
a stack of dies coupled to the microelectronic component,
wherein the stack of dies includes a first die comprising cache memory and a second die comprising tags for determining whether a requested piece of data is available in the cache memory, and
wherein the cache memory includes transistors of a first transistor architecture, the tags include transistors of a second transistor architecture, and the microelectronic component is one of an interposer, a package substrate, a circuit board, or a further die.

20. The microelectronic assembly according to claim 19, wherein the cache memory includes dynamic random-access memory (DRAM) cells, and the tags include static random-access memory (SRAM) cells.
